(19) United States
(12) Patent Application Publication
(10) Pub. No.: US 2015/0001456 A1
(43) Pub. Date: Jan. 1, 2015

(54) RESISTANCE VARIABLE ELEMENT, SEMICONDUCTOR DEVICE INCLUDING IT AND MANUFACTURING METHODS THEREFOR

(71) Applicants: Naoki Banno, Tokyo (JP); Munehiro Tada, Tokyo (JP)

(72) Inventors: Naoki Banno, Tokyo (JP); Munehiro Tada, Tokyo (JP)

(73) Assignee: NEC CORPORATION, Minato-ku, Tokyo (JP)

(21) Appl. No.: 14/117,306

(22) PCT Filed: May 10, 2012
(86) PCT No.: PCT/JP2012/062059

§ 371 Date: Nov. 12, 2013

(30) Foreign Application Priority Data
May 10, 2011 (JP) 2011-105424

(51) Int. Cl. H01L 45/00

(52) U.S. Cl. CPC H01L 45/1266; H01L 45/085; H01L 45/1633; H01L 45/146
USPC 257/4; 438/104

(57) ABSTRACT

A resistance variable element includes a first electrode, a second electrode and an ion conductor layer interposed between the first and second electrodes. Metal ions supplied from the first electrode into the ion conductor layer accept electrons from the second electrode and are turned into metal. The so formed metal is precipitated to cross-link and interconnect the first and second electrodes to provide for voltage variations. The ion conductor layer has a stacked layer structure comprised of a first ion conductor layer formed by a compound containing oxygen and carbon and a second ion conductor layer formed by a metal oxide. The metal oxide that forms the second ion conductor layer includes at least one out of zirconium oxide and hafnium oxide.

### CROSS-REFERENCE TO RELATED APPLICATION

The present application is a National Stage Entry of PCT/JP2012/062059 filed May 10, 2012, which is based on and claims the benefit of the priority of JP Patent Application 2011-105424 filed in Japan on May 10, 2011. The disclosures of all of which are incorporated herein their entirety by reference.

### TECHNICAL FIELD

This invention relates to a resistance variable element that is used in an electronic device, such as a programmable logic or memory, and that exploits precipitation of metal. The invention also relates to a semiconductor device including the resistance variable element, a method for manufacturing the resistance variable element and to a method for manufacturing the semiconductor device.

### BACKGROUND

To diversify the functions of the programmable logic to promote its implementation on electronic equipment or the like, it is necessary to reduce the size of a switch interconnecting logic cells as well as its on-resistance. In a well-known manner, a switch (switching element) that exploits metal precipitation in an ion conductor layer, through which metal ions are migrated, is smaller in size and lesser in on-resistance than a conventional semiconductor switch.

Among switching elements of this sort, there are a two-terminal switch (FIG. 1), disclosed in Patent Literature 1, and a three-terminal switch (FIG. 2), disclosed in Patent Literature 2. The two-terminal switch is comprised of a first electrode supplying metal ions, a second electrode not supplying metal ions and an ion conductor layer sandwiched between the first and second electrodes. The two electrodes are switched by buildup and extinction of a metal bridge within the ion conductor layer. The two-terminal switch is simplistic in structure and hence the process for fabrication thereof is also simplistic, such that it is possible to reduce the switch size to a nanometer order. The three-terminal switch is of such a structure in which the second electrodes of two two-terminal switches are unified together, and is of high reliability.

Preferably, the ion conductor layer is formed by a porous polymer mainly composed of silicon, oxygen and carbon. The porous polymer ion conductor layer is able to maintain a high dielectric breakdown voltage even after buildup of the metal bridge and hence is excellent in operation reliability (Patent Literature 3).

To get such switch loaded as a wire changeover switch in a programmable logic, it is necessary to reduce the switch size by way of elevating the switch density and to simplify the fabrication process. The wire material for vanguard semiconductor devices is mainly copper, such that there is a demand for a technique that enables a resistance variable element to be efficiently constructed within a copper wiring.

Non-Patent Literature 1 discloses a technique to integrate a switching element exploiting an electrochemical reaction into a semiconductor device. Specifically, such technique is shown in which a copper wire on a semiconductor substrate is used at the same time as a first electrode of the switching element. If such structure is used, a step of newly constructing a first electrode may be dispensed with. Thus, a mask to be used to form the first electrode is unneeded so that the number of photomasks (PRs) to be added for fabrication of the resistance variable element is two. If, in this case, the ion conductor layer is directly formed on the copper wire, the surface of the copper wire is oxidized to increase the leakage current. Hence, a thin metal film, operating as a sacrificed oxide layer, is interposed between the copper wire and the ion conductor layer. The thin metal film is oxidized by oxygen contained in the ion conductor layer to form a portion of the ion conductor layer.
Patent Literature 1 JP Patent Kohyo Publication JP-P2002-536840A
Patent Literature 2 JP Patent Kokai Publication JP-P2010-216732A
Patent Literature 3 JP Patent Kokai Publication JP-P2009-258007A

### [Non-Patent Literature 1]

Non-Patent Literature 1: M Tada et al., IEEE TRANSACTION ON ELECTRON DEVICES (IEEE Transaction on Electron Devices), Vol. 57, pp. 1987-1995, 2010
Non-Patent Literature 2: J. Noguchi, IEEE TRANSACTION ON ELECTRON DEVICES (2005 IEEE Transactions on Electron Devices), Vol. 52, pp. 1743-1750, 2005

### SUMMARY

The disclosures of the above mentioned Patent Literatures and Non-Patent Literatures are to be incorporated herein by reference.

The following analysis is given by the present inventors. It is preferred that a wire changeover switch of a programmable logic has a high on/off resistance ratio. Since the current path in the on-state of a switch exploiting a metal bridge is an aggregation of metal, the resistance value during the on-time may be made sufficiently low. On the other hand, the resistance value for the off-state is the same as the initial resistance of the device. The metal bridge switch of the structure disclosed in Non-Patent Literature 1 suffers a drawback that much leakage current is generated during off time so that high resistance may not be maintained during the off-time.

The conventional technique is beset with a difficult problem, as stated above, such that solution of the problem is felt to be desirable. It is thus an object of the present invention to provide a resistance variable element (switching element) having a high off-resistance, a reconfigurable semiconductor device exploiting the resistance variable element, a method for manufacturing the semiconductor device, and a method for manufacturing the switching element.

In a first aspect of the present disclosure, there is provided a resistance variable element comprising a first electrode, a second electrode and an ion conductor layer interposed between the first and second electrodes. Metal ions supplied from the first electrode into the ion conductor layer accept electrons from the second electrode and are turned into metal which is precipitated. The metal cross-links and interconnects the first and second electrodes to provide for variations in the resistance of the element. The ion conductor layer is a stacked layer structure made up by a first ion conductor layer formed by a compound containing oxygen and carbon and a second ion conductor layer formed of a metal oxide. The metal oxide that forms the second ion conductor layer contains at least one out of zirconium oxide and hafnium oxide.

In a second aspect of the present disclosure, there is provided a semiconductor device including a multi-layered copper wiring on a semiconductor substrate thereof and a resistance variable element as a two-terminal structure, in which the resistance variable element is disposed in an inner side of the multi-layered copper wiring. The multi-layered copper wiring includes at least a copper wire(s) and a copper plug.

The resistance variable element is made up of an upper electrode as a second electrode, a lower electrode(s) as a first electrode and an ion conductor layer interposed in-between the upper electrode and the lower electrode(s). The copper wire(s) is simultaneously used as the lower electrode(s). A barrier insulating film is formed on top of the copper wire(s). The barrier insulating film is formed of silicon nitride.

An opening part that reaches the copper wire(s) is formed in the barrier insulating film. The ion conductor layer and the upper electrode of the resistance variable element are sequentially embedded only in the opening part. The upper electrode is formed of ruthenium. The upper electrode is connected via a barrier metal to the copper plug. The first ion conductor layer is made up of a first ion conductor layer contacted with the copper wire(s) and a second ion conductor layer contacted with the upper electrode. The first ion conductor layer is mainly formed by a polymer film, with a specific inductive capacity of 2.1 or higher to 3.0 or lower, mainly composed at least of silicon, oxygen and carbon.

In a third aspect of the present disclosure, there is provided a semiconductor device including a multi-layered copper wiring on a semiconductor substrate thereof and a resistance variable element disposed in an inner side of the multi-layered copper wiring. The multi-layered copper wiring includes at least a copper wire(s) and a copper plug. The resistance variable element is made up of two of lower electrode(s) as the first electrode, an upper electrode as the second electrode, and an ion conductor layer interposed in-between the upper electrode and the lower electrodes. The copper wire(s) is simultaneously used as two of the lower electrodes. A barrier insulating film is formed on top of the copper wire(s), and is formed of silicon nitride. The barrier insulating film includes a single opening part that reaches copper wires which are both of the two lower electrodes. The ion conductor layer and the upper electrode are sequentially embedded only in the opening part. The upper electrode is formed of ruthenium. The upper electrode is connected via a barrier metal to the copper plug. The ion conductor layer is made up of a first ion conductor layer contacted with the copper wire(s) and a second ion conductor layer contacted with the upper electrode. The first ion conductor layer is mainly formed by a polymer film, with a specific inductive capacity of 2.1 or higher to 3.0 or lower, and is mainly composed at least of silicon, oxygen and carbon.

In a fourth aspect of the present disclosure, there is provided a method for manufacturing a resistance variable element including a first electrode, a second electrode and an ion conductor layer interposed between the first and second electrodes. The ion conductor layer is a stacked layer structure of a first ion conductor layer formed by a compound containing oxygen and carbon and a second ion conductor layer formed of a metal oxide. The method comprises the steps of forming at least one first electrode on the surface of a silicon substrate, forming a metal layer containing at least one metal out of zirconium and hafnium on the silicon substrate, and forming a first ion conductor layer formed by a compound containing oxygen and carbon on the metal layer in an oxidizing atmosphere. In the step of forming the first ion conductor layer in the oxidizing atmosphere, the metal layer is simultaneously oxidized to form the second ion conductor layer.

In a fifth aspect, there is provided a method for manufacturing a semiconductor device including a multi-layered copper wiring arranged on a semiconductor substrate and a resistance variable element of a two-terminal structure. The resistance variable element is disposed in an inner side of the multi-layered copper wiring. The multi-layered copper wiring of the semiconductor device includes at least one copper wire. The method comprises the steps of forming a barrier insulating film on at least one copper wire that is used simultaneously as a lower electrode, and forming, in the barrier insulating film, an opening part that reaches the at least one copper wire. The method further comprises the steps of forming, on the copper wire in at least the opening, a metal layer containing at least one metal out of zirconium and hafnium, and forming a first ion conductor layer formed by a compound containing oxygen and carbon on the metal layer in an oxidizing atmosphere. The metal layer is oxidized simultaneously in the step of forming the first ion conductor layer in the oxidizing atmosphere to form the second ion conductor layer.

In a sixth aspect, there is provided a method for manufacturing a semiconductor device including a multi-layered copper wiring arranged on a semiconductor substrate and a resistance variable element of a two-terminal structure arranged in an inner side of the multi-layered copper wiring. The multi-layered copper wiring of the semiconductor device includes at least two copper wires. The method comprises the steps of forming a barrier insulating film on the two copper wires, used simultaneously as lower electrodes, and forming, in the barrier insulating film, an opening part that reaches the two copper wires. The method further comprises the steps of forming, on the two copper wires in at least the opening part, a metal layer containing at least one metal out of zirconium and hafnium, and forming a first ion conductor layer formed by a compound containing oxygen and carbon on the metal layer in an oxidizing atmosphere. The metal layer is oxidized simultaneously at the step of forming the first ion conductor layer in the oxidizing atmosphere to form the second ion conductor layer.

In a metal cross-link bridge, the leakage current depends on the material type as well as the film quality of the ion conductor layer. In particular, the amount of the leakage current is appreciably varied as a result of diffusion of conductive metal through the ion conductor layer. It is thus necessary that, during fabrication of the switch element and during the time of application of a voltage lower than a switching voltage, as small an amount of metal ions as possible is supplied from the first electrode that supply metal ions. Metal ions are delivered into the ion conductor layer by a metal ionizing reaction. In ionizing a cation-producing metal, the presence of anions, operating as oxidizing agent, is necessary. In case oxygen is contained in the ion conductor layer, oxygen ions present in the ion conductor layer operates as oxidizing agent to accelerate the metal ionizing reaction.

For example, in forming copper wiring for LSI, shorting across copper wires due to implantation of copper ions from the copper wire into the interlayer insulating film is at issue (time dependent dielectric breakdown (TDDB) life). In particular, reports have been made that, in case a copper oxide layer is produced in the course of chemical mechanical polishing (CMP) as a part of the copper wiring forming process, the TDDB life becomes shorter (Non-Patent Literature 1). That is, implantation of copper ions into the interlayer insulating film is accelerated. In the above switch, the rate of implantation of metal of the first electrode into the ion conductor layer is changed in dependence upon the state of formation of copper oxide.

In the switch element according to the present invention, zirconium (Zr), hafnium (Hf) or further aluminum (Al), having thermal stability higher than that of titanium (Ti) or tantalum (Ta), used heretofore, is used to operate as a sacrificed oxide layer introduced on top of the first electrode, such as to suppress formation of a copper oxide layer.

According to the present invention, leakage current during the off-time may be decreased. Thus, in case the present switch is used as a wire changeover switch for a programmable switch array, power consumption during the operation time may be suppressed. On the other hand, the leakage current may be maintained at a lower value in case a plurality of memory devices are interconnected in parallel, and hence a large number of memory devices can be written in simultaneously.

### BRIEF DESCRIPTION OF DRAWINGS

FIG. 1 is a schematic cross-sectional view showing an exemplary configuration of a conventional two-terminal switching element.

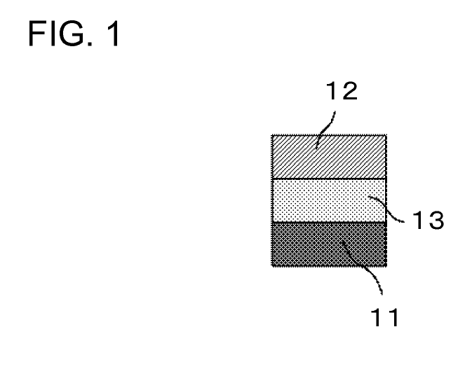

FIG. 2 is a schematic cross-sectional view showing an exemplary configuration of a two-terminal switching element according to an Example.

FIG. 3 is a schematic cross-sectional view showing the two-terminal switching element shown in FIG. 2.

FIG. 4 shows exemplary manufacturing process steps, in cross-sectional views, for a two-terminal switching element according to an Example.

FIG. 5 is a schematic cross-sectional view showing an exemplary configuration of a semiconductor device that uses a two-terminal switching element according to an Example.

FIG. 6 is a graph showing switching characteristics of the exemplary semiconductor device shown in FIG. 5.

FIG. 7 is a graph showing other switching characteristics of the exemplary semiconductor device shown in FIG. 5.

FIG. 8 shows, in cross-sectional views, exemplary manufacturing process steps of the semiconductor device shown in FIG. 5.

FIG. 9 shows, in cross-sectional views, exemplary manufacturing process steps of the semiconductor device shown in FIG. 5.

FIG. 10 shows, in cross-sectional views, exemplary manufacturing process steps of the semiconductor device shown in FIG. 5.

FIG. 11 is a schematic cross-sectional view showing an exemplary configuration of a semiconductor device that uses a three-terminal switching element according to an Example.

FIG. 12 shows, in cross-sectional views, exemplary manufacturing process steps of the semiconductor device shown in FIG. 11.

FIG. 13 shows, in cross-sectional views, exemplary manufacturing process steps of the semiconductor device shown in FIG. 11.

FIG. 14 shows, in cross-sectional views, exemplary manufacturing process steps of the semiconductor device shown in FIG. 11.

FIG. 15 shows, in cross-sectional views, exemplary manufacturing process steps of the semiconductor device shown in FIG. 11.

### PREFERRED MODES

In the first aspect, the second ion conductor layer is preferably a layered product of titanium oxide and zirconium oxide, a mixed product of titanium oxide and zirconium oxide, a layered product of titanium oxide and hafnium oxide or a mixed product of titanium oxide and hafnium oxide.

Or, the second ion conductor layer is preferably a layered product of hafnium oxide and zirconium oxide, a mixed product of hafnium oxide and zirconium oxide, a layered product of hafnium oxide and aluminum oxide, a mixed product of hafnium oxide and aluminum oxide, a layered product of zirconium oxide and aluminum oxide or a mixed product of zirconium oxide and aluminum oxide.

Preferably, the second ion conductor layer further contains aluminum oxide.

Also preferably, the first electrode contains copper.

Also preferably, the film thickness of the second ion conductor layer is 0.5 nm or more to 3 nm or less.

Preferably, two optional ones of the resistance variable elements may be arrayed side-by-side, and the first electrodes of the two resistance variable elements may be formed as one, or the second electrodes of the two resistance variable elements may be formed as one.

Preferably, the first ion conductor layer is mainly composed at least of silicon, oxygen and carbon and is formed by a polymer film having a specific inductive capacity of 2.1 or higher to 3.0 or lower.

In fourth to sixth aspects, preferably the step of forming the metal layer is the step of forming a layered product of titanium oxide and zirconium oxide, a mixed product of titanium oxide and zirconium oxide, a layered product of titanium oxide and hafnium oxide, a mixed product of titanium oxide and hafnium oxide, a layered product of hafnium oxide and zirconium oxide, a mixed product of hafnium oxide and zirconium oxide, a layered product of hafnium oxide and aluminum oxide, a mixed product of hafnium oxide and aluminum oxide, a layered product of zirconium oxide and aluminum oxide and a mixed product of zirconium oxide and aluminum oxide.

### EXAMPLES

### Example 1

### Configuration

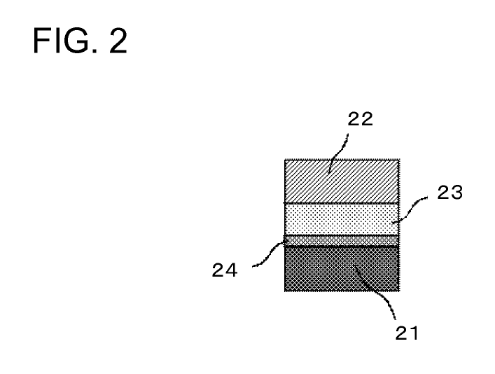

A configuration of a two-terminal switching element of Example 1 will now be explained. FIG. 2 depicts a schematic cross-sectional view showing a two-terminal switching element according to Example 1.

The switching element of the present Example 1 includes a first electrode 21, a second ion conductor layer 24 formed on an interface to the first electrode 21 and a first ion conductor layer 23 contiguous to the second ion conductor layer 24. The switching element also includes a second electrode 22 formed on a layered product of the first electrode 21 and the ion conductor layers 24, 23. The first and second ion conductor layers 23, 24 play the role of a medium via which metal ions are migrated. The second electrode 22 is preferably of such a material that, when voltage is applied to the second electrode, the latter does not supply metal ions to the first ion conductor layer 23 or to the second ion conductor layer 24.

The first electrode 21 is of copper, and is formed by sputtering, chemical vapor deposition (CVD) or electroplating.

The second ion conductor layer 24 is formed of a metal oxide. Initially, such metal that may be oxidized to an oxide is deposited on the first electrode 21, and the first ion conductor layer 23, containing oxygen, is then deposited on the metal. During deposition of the oxygen-containing first ion conductor layer 23 on the metal, the metal is oxidized with oxygen present in a processing chamber to form the ion conductor layer 24 as a metal oxide interface. As a candidate for the metal, such element that may be used for High-k metal gate, such as Zr, Hf or Al, is desirable. These are valve metals that are low in the standard Gibbs energy in forming an oxide and that are more liable to form corresponding oxides. Additionally, these metals are higher in thermal stability than Ti or Ta and hence operate effectively as an oxygen getter during deposition of the ion conductor layer to prevent the copper wire surface from becoming oxidized. The second ion conductor layer is of a film thickness which is most preferably 2 nm and which may desirably be not less than 0.5 nm and not greater than 3 nm. If the film thickness is thinner than this range, the copper wire surface may become oxidized only slightly. If, on the other hand, the film thickness is thicker than the range, the metal material is not fully oxidized but may be left as metal.

The second ion conductor layer 24 may also be formed by oxidizing a layered structure of Ti with Zr, Hf or Al or by oxidizing a mixed metal of Ti with Zr, Hf or Al. Since Ti is high in tight adhesion performance, it may enhance tightness of adhesion to the first ion conductor layer 23 and to the first electrode 21 to raise a dielectric breakdown voltage. On the other hand, Zr is effective to prevent metal of a first lower electrode 55a from becoming oxidized.

The second ion conductor layer 24 may also be formed by oxidizing a layered structure of Hf—Zr, Hf—Al or Zr—Al or by oxidizing a mixed metal of Hf—Zr, Hf—Al or Zr—Al. It is desirable not to use, for the wire changeover switch, as such, a high specific inductive capacity material that will possibly cause signal delay. Thus, such metal that, when oxidized, is enhanced in specific inductive capacity as oxide, is layered or mixed together with such metal that, when oxidized, is lower in specific inductive capacity as oxide than the first-stated metal, thereby lowering the overall specific inductive capacity. If the specific inductive capacity is low, the capacitive component inherently present in the switching element is decreased, such that, when the switching element is used as part of the wiring during on-time, signal delay may be decreased. In the present Example, the specific inductive capacity of not less than 2.1 and not higher than 3.0 is preferred.

A metal that is to form the second ion conductor layer is deposited using sputtering, laser ablation or plasma CVD. Preferably, the second ion conductor layer 24 is of a film thickness not greater than 50% of that of the first ion conductor layer 23.

The first ion conductor layer 23, which is a SiOCH based polymer film containing silicon, oxygen, carbon and hydrogen, as an example, may be deposited by plasma CVD. A feedstock material of cyclic organic siloxane and helium as a carrier gas are allowed to flow into a reaction chamber. When the supply of the two materials is stabilized, with the pressure within the reaction chamber being constant, supply of the RF power is commenced. The feedstock material is supplied at a rate of 10 to 200 sccm, and helium is supplied into the reaction chamber via a feedstock vaporizer at a rate of 500 sccm, while also being supplied directly into the chamber via a separate line at a rate of 500 sccm.

It is sufficient that the second electrode is formed of ruthenium, platinum or nickel. From the processing perspective, ruthenium is preferred for relative ease in etching.

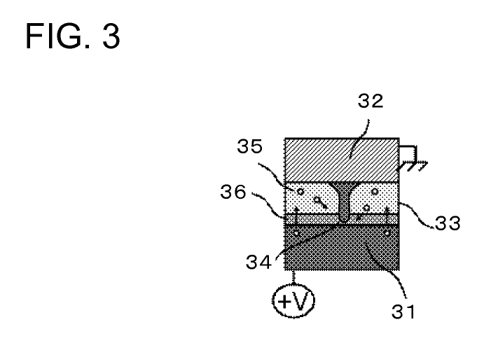

A method for driving the two-terminal switching element of the subject Example 1 will now be explained with reference to FIG. 3 which is a schematic cross-sectional view for illustrating the driving principle of the two-terminal switching element shown in FIG. 2.

A second electrode 32 is grounded, and a positive voltage is applied to a first electrode 31. This causes metal of the first electrode 31 to be turned via the second ion conductor layer 36 into metal ions 35 which are then dissolved in a first ion conductor layer 33. The metal ions 35 in the second ion conductor layer 36 and in the first ion conductor layer 33 are precipitated on a surface of the second electrode 32 in the form of a metal bridge 34. The first electrode 31 is connected to the second electrode 32 by the metal bridge 34 precipitated. The switch is turned on when the first electrode 31 and the second electrode 32 are electrically connected to each other via the metal bridge 34.

If, in the above mentioned on-state, the second electrode 32 is grounded, and a negative voltage is applied to the first electrode 31, the metal bridge 34 is dissolved as metal ions 35 in the second ion conductor layer 36 and in the first ion conductor layer 33, thus rupturing part of the metal bridge 34. The metal ions 35 are restored at this time by the metal bridge 34, scattered in the second ion conductor layer 36 and in the first ion conductor layer 33, and by the first electrode 31. This breaks electrical connection between the first electrode 31 and the second electrode 32 to turn off the switch. To switch from the off-state again to the on-state, it is sufficient to apply a positive voltage to the first electrode 31 again. It is also possible that, as the first electrode 31 is grounded, a negative voltage is applied to the second electrode 32 to turn on the switch, or that, as the first electrode 31 is grounded, a positive voltage is applied to the second electrode 32 to turn off the switch.

It should be noticed that, when the switch is turned off, there occur changes in electrical characteristics first, such that, for example, the resistance between the first electrode 31 and the second electrode 32 is increased or the capacitance between the electrodes is varied. These changes are initiated as from the time prior to complete breakage of the electrical connection. The electrical connection is ultimately broken after such changes in the electrical characteristics.

### (Manufacturing Method)

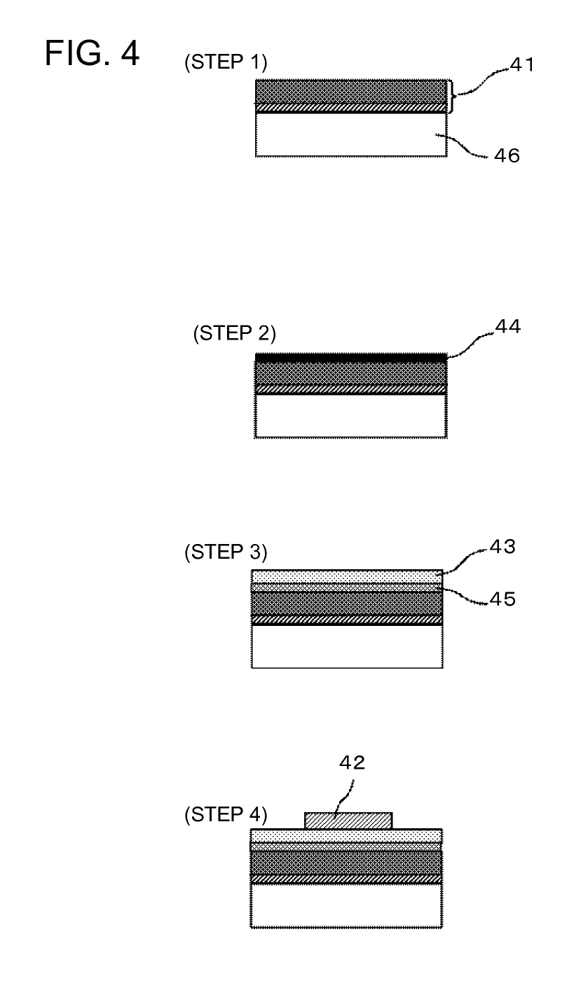

An exemplary manufacturing method of the switching element of the present Example will now be described. Reference is made to FIG. 4 by way of explanation of the process steps for manufacturing the switch. FIG. 4 depicts a schematic cross-sectional view showing exemplary process steps for manufacturing a two-terminal switching element of the present Example.

### [Step 1]

On a surface of a low resistance silicon substrate 46, tantalum is deposited by sputtering to a film thickness of 20 nm and copper is then deposited thereon by sputtering to a film thickness of 10 nm, thereby providing a first electrode 41.

### [Step 2]

Zr, Hf or Al is deposited by sputtering to a thickness of 1 nm. Alternatively, Ti and Zr are deposited by sputtering, each to a film thickness of 0.5 nm, Ti and Hf are deposited by sputtering, each to a film thickness of 0.5 nm, or Ti and Al are deposited by sputtering, each to a film thickness of 0.5 nm. Thus, a metal layer 44 is formed.

### [Step 3]

As a first ion conductor layer 43, a SIOCH based polymer film, containing silicon, oxygen, carbon and hydrogen, is formed by plasma CVD. A feedstock material of cyclic organic siloxane and helium as a carrier gas are allowed to flow into a reaction chamber. When the supply of the two materials is stabilized, with the pressure within the reaction chamber being constant, supply of the RF power is commenced. The feedstock material is supplied at a rate of 10 to 200 sccm, and helium is supplied into the reaction chamber via a feedstock vaporizer for the feedstock material at a rate of 500 sccm, while also being supplied directly into the reaction chamber via a separate line at a rate of 500 sccm. The metal layer 44, exposed to the feedstock material of the SIOCH based polymer film, containing oxygen, is oxidized on its own in the course of forming the first ion conductor layer 43, thus providing a second ion conductor layer 45.

### [Step 4]

On the first ion conductor layer 43, ruthenium is deposited to a film thickness of 30 nm by vacuum evaporation or sputtering. At this time, ruthenium is deposited via a shadow mask formed of stainless steel or silicon to form a square-shaped second electrode 42 with each side being 30 to 150 μm in length.

### Example 2

A semiconductor device, within a multi-layered wiring of which has been formed a two-terminal switching element, such as that according to Example 1, will now be explained as Example 2.

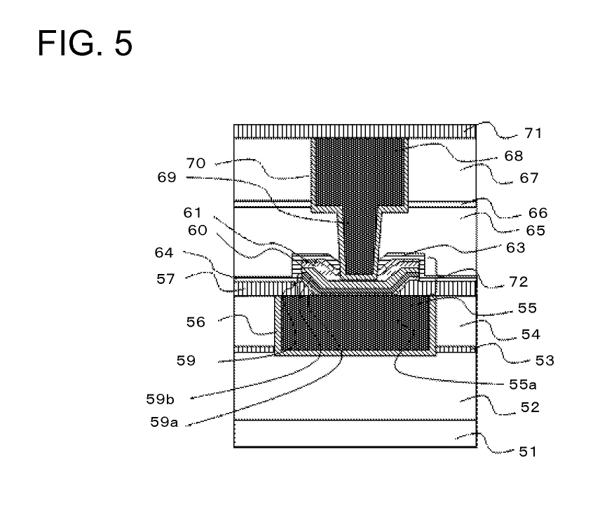

FIG. 5 depicts a partial cross-sectional view schematically showing a configuration of the semiconductor device of Example 2. A two-terminal switch 72 is provided in an inner side of the multi-layered wiring formed on a semiconductor substrate 51.

The multi-layered wiring includes an interlayer insulating film 52, a barrier insulating film 53, an interlayer insulating film 54, a barrier insulating film 57, a protective insulating film 64, an interlayer insulating film 65, an etching stopper film 66, an interlayer insulating film 67 and a barrier insulating film 71, arranged in this order on top of a semiconductor substrate 51.

In the multi-layered wiring, a first wire 55 is embedded, via a barrier metal 56, in wire trenches formed in the interlayer insulating film 54 and in the barrier insulating film 53.

In the multi-layered wiring, a second wire 68 is embedded in wire trenches formed in the interlayer insulating film 67 and in the etching stopper film 66. A plug 69 formed as one with the second wire 68 is embedded in a pilot hole provided in the interlayer insulating film 65, the protective insulating film 64 and in a hard mask film 63. Lateral sides and bottom sides of the second wire 68 and the plug 69 are covered by a barrier metal 70.

In the multi-layered wiring, a two-terminal switch 72 is formed in an opening part provided in the barrier insulating film 57, on top of the first wire 55, which is to operate as a lower electrode, on a wall surface section of the opening part in the barrier insulating film 57 and on the barrier insulating film 57. The two-terminal switch is made up by a resistance variable layer 59, a first upper electrode 60 and a second upper electrode 61. The hard mask film 63 is formed on top of the second upper electrode 61. Upper and lateral surface sections of a layered product, made up by an oxidation inhibiting film 59a, an ion conductor layer 59b, the first upper electrode 60, second upper electrode 61 and the hard mask film 63, are covered by the protective insulating film 64.

A portion of the first wire 55 is oxidized so that the first lower electrode 55a forms a lower electrode of the two-terminal switch 72, that is, the first wire 55 operates at the same time as the first lower electrode 55a of the two-terminal switch 72. It is thus possible to lower the electrode resistance as the number of the process steps is reduced. The two-terminal switch may be loaded in position by preparing a mask set of at least 2×PR by way of an additional step to the usual copper damascene wiring forming process, thus achieving both the low resistance of the switching element and low costs at the same time.

In the two-terminal switch 72, the oxidation inhibiting film 59a and the first lower electrode 55a are directly contacted with each other in a region of the opening part provided in the barrier insulating film 57. The ion conductor layer 59b and the first upper electrode 60 are directly contacted with each other. The plug 69 is electrically connected to the second upper electrode 61 via the barrier metal 70 on top of the second upper electrode 61. The two-terminal switch 72 is controlled to be on or off by applying a voltage or causing the current to flow. For example, electricodiffusion of metal of the first wire 55 into the oxidation inhibiting film 59a and into the ion conductor layer 59b is exploited to manage on/off control.

The semiconductor substrate 51 is such substrate carrying a semiconductor device thereon, and may, for example, be a silicon substrate, a single-crystal substrate, an SOI (Silicon on Insulator) substrate, a TFT (Thin Film Transistor) substrate or a substrate for manufacturing liquid crystal. The interlayer insulating film 52 is such insulating film that is formed on the semiconductor substrate 51. For the interlayer insulating film 52, a silicon oxide film or a low dielectric constant film, such as a SiOCH film, which is lower in specific inductive capacity than the silicon oxide film, may be used. The interlayer insulating film 52 may be made up by a plurality of insulating films layered together.

The barrier insulating film 53 is such insulating film that exhibits a barrier characteristic and that is interposed between the interlayer insulating films 52, 54. At the time of machining a wire trench for the first wire 55, the barrier insulating film 53 operates as an etch stop layer. The barrier insulating film 53 may, for example, be formed of silicon nitride, SiC or SiCN. A wire trench, in which the first wire 55 is to be embedded, is formed in the barrier insulating film 53. The first wire 55 is embedded in the wire trench via the barrier metal 56. The barrier insulating film 53 may be omitted depending on the wire trench etch conditions selected.

The interlayer insulating film 54 is such insulating film that is formed on the barrier insulating film 53. For the interlayer insulating film 54, a silicon oxide film or a low dielectric constant film, lower in specific inductive capacity than the silicon oxide film, such as a SiOCH film, may be used. The interlayer insulating film 54 may be made up by a plurality of insulating films layered together. A wire trench, in which the first wire 55 is to be embedded, is formed in the interlayer insulating film 54. The first wire 55 is embedded in the wire trench via the barrier metal 56.

The first wire 55 is such wire that is embedded via the barrier metal 56 in wire trenches formed in the interlayer insulating film 54 and in the barrier insulating film 53. The first wire 55 is used at the same time as a lower electrode of the two-terminal switch 72 and is directly contacted with the oxidation inhibiting film 59a. The ion conductor layer 59b has its lower surface directly contacted with the oxidation inhibiting film 59a, while having its upper surface directly contacted with the first upper electrode 60. The first wire 55 is formed of a metal, such as copper, which is able to be diffused or allows ion conduction in the resistance variable layer 59. The first wire 55 may also be alloyed with aluminum.

The barrier metal 56 is an electrically conductive film exhibiting a barrier characteristic. That is, the barrier metal coats lateral and bottom sides of the wire to prevent metal of the first wire 55 from becoming diffused into the interlayer insulating film 54 or into underlying layers. In case the first wire 55 is formed of a metal element, mainly copper, the barrier metal 56 may be films of high melting metals or nitrides thereof, such as tantalum, tantalum nitride, titanium nitride or wolfram carbonitride films, or corresponding layered films.

The barrier insulating film 57, formed on the interlayer insulating film 54, provided with the first wire 55, prevents metal of the first wire 55, such as copper, from becoming oxidized, while preventing metal of the first wire 55 from being diffused into the interlayer insulating film 65. The barrier insulating film at the same time operates as an etching stop layer at the time of machining the upper electrodes 61, 60 or the resistance variable layer 59. The barrier insulating film 57 may, for example, be a SiC film, a SiCN film, a film of silicon nitride or layered films thereof. Preferably, the barrier insulating film 57 is formed of the same material as that of the protective insulating film 64 or the hard mask film 63.

The oxidation inhibiting film 59a and the ion conductor layer 59b are variable resistance films. They may be formed of a material whose resistance is varied due to the operation, such as diffusion or ion conduction, of the metal of the first wire 55 (lower electrode). They may be formed of a material capable of ion conduction in case resistance change of the two-terminal switch 72 is produced by precipitation of metal ions.

The ion conductor layer 59b is formed by the plasma CVD method. A feedstock material of cyclic organic siloxane and helium as a carrier gas are allowed to flow into a reaction chamber. When the supply of the two materials is stabilized, with the pressure within the reaction chamber being constant, supply of the RF power is commenced. The feedstock material is supplied at a rate of 10 to 200 sccm, and helium is supplied via a feedstock vaporizer at a rate of 500 sccm, while being also directly supplied into the reaction chamber via a separate line at a rate of 500 sccm.

The oxidation inhibiting film 59a performs the dual roles: That is, it prevents metal of the first lower electrode 55a from being diffused into the ion conductor layer 59b due to the plasma or to heating during deposition of the ion conductor layer 59b, while also preventing the first lower electrode 55a from being oxidized to promote diffusion. Metals of the oxidation inhibiting film 59a, such as Zr, Hf and Al, are turned into zirconium oxide, hafnium oxide or aluminum oxide during deposition of the ion conductor layer 59b. These oxides form part of the ion conductor layer 59b. The oxidation inhibiting film 59a of metal is of a film thickness which is most preferably 2 nm and which may desirably be not less than 0.5 nm and not greater than 3 nm. If the film thickness is thinner than this range, the copper wire surface may become oxidized only slightly. If, on the other hand, the film thickness is thicker than the above range, the metal material is not fully oxidized but may be left as metal. The resistance variable layer 59 is formed on the first lower electrode 55a, a tapered surface of the opening part in the barrier insulating film 57 and on the barrier insulating film 57. The resistance variable layer 59 is provided in such a manner that at least an outer rim of a connection part between the first lower electrode 55a and the resistance variable layer 59 will be extended at least along a tapered surface of the opening part of the barrier insulating film 57.

In forming the oxidation inhibiting film 59a, Ti may be layered on Zr, Hf or Al, or Ti may be mixed with Zr, Hf or Al. Since Ti is high in its adhesion characteristic, it is effective to improve tight adhesion to the ion conductor layer 59b and to the first lower electrode 55a to elevate the dielectric breakdown voltage. The oxidation inhibiting film 59a may be formed by oxidizing a layered structure of Hf—Zr, Hf—Al or Zr—Al or by oxidizing mixed metal Hf—Zr, Hf—Al or Zr—Al. It is desirable not to use a high specific inductive capacity material, as a wire changeover switch, that will possibly cause signal delay. Thus, a metal that, if oxidized, will form an oxide of high specific inductive capacity, and another metal that, if oxidized, will form an oxide lower in specific inductive capacity than the oxide of the first stated metal, are layered or mixed together to lower the overall specific inductive capacity.

The first upper electrode 60 is a lower layer electrode of the upper electrode of the two-terminal switch 72, and is directly contacted with the ion conductor layer 59b. For the first upper electrode 60, such metal is used that is less liable to be ionized or that is less susceptible to diffusion or ion conduction in the ion conductor layer 59b than the metal of the first wire 55. Examples of such metal include platinum, ruthenium and nickel.

The second upper electrode 61 is an upper layer electrode of the upper electrode of the two-terminal switch 72, and is formed on the first upper electrode 60. The second upper electrode 61 plays the role of protecting the first upper electrode 60. That is, the second upper electrode 61 protects the first upper electrode 60 such as to suppress damages otherwise done to the first upper electrode 60 in the course of the process to maintain the switching characteristic of the two-terminal switch 72. The second upper electrode 61 may be formed of, for example, tantalum, titanium, wolfram or nitrides thereof.

The hard mask film 63 is used both as a hard mask at the time of etching the second upper electrode 61, first upper electrode 60, ion conductor layer 59b and the oxidation inhibiting film 59a, and as a passivation film. The hard mask film 63 may, for example, be a SiN film. Preferably, the hard mask film 63 is formed of the same material as the protective insulating film 64 and the barrier insulating film 57. That is, the material lying around the two-terminal switch 72 is the same material throughout. In this case, the material interface is unified to prevent intrusion of moisture from outside as well as to prevent oxygen from being desorbed from the two-terminal switch 72 itself.

The protective insulating film 64 is such insulating film that has the function to prevent oxygen from being desorbed from the ion conductor layer 59b without damaging the two-terminal switch 72. Preferably, the protective insulating film 64 may, for example, be a silicon nitride film or a SiCN film. Also preferably, the protective insulating film 64 is of the same material as that of the hard mask film 63 and the barrier insulating film 57. In case the respective films are of the same material, the protective insulating film 64, barrier insulating film 57 and the hard mask film 63 may be unified to provide for improved tightness of interfacial adhesion and improved protection of the two-terminal switch 72.

The interlayer insulating film 65 is such insulating film that is formed on the protective insulating film 64. As the interlayer insulating film 65, a silicon oxide film, a SiOC film or a low dielectric constant film, such as SiOCH film, which is lower in specific inductive capacity than the silicon oxide film, may be used. The interlayer insulating film 65 may be composed by a plurality of insulation films stacked together. The interlayer insulating film 65 may be of the same material as that of the interlayer insulating film 67. A pilot hole, in which the plug 69 is to be embedded, is formed in the interlayer insulating film 65. The plug 69 is embedded via the barrier metal 70 in the pilot hole.

The etching stopper film 66 is an insulating film interposed between the interlayer insulating films 65, 67. The etching stopper film 66 plays the role as an etching stop layer during machining a wire trench for the second wire 68. For the etching stopper film 66, a SiN film, a SiC film or a SiCN film, for example, may be used. A wire trench, in which the second wire 68 is to be embedded, is formed in the etching stopper film 66. The second wire 68 is embedded in the wire trench via the barrier metal 70. The etching stopper film 66 may be omitted depending on the wire trench etch conditions selected.

The interlayer insulating film 67 is formed on top of the etching stopper film 66. As the interlayer insulating film 67, a silicon oxide film, a SiOC film or a low dielectric constant film whose specific inductive capacity is lower than that of the silicon oxide film, such as SiOCH film, for example, may be used. The interlayer insulating film 67 may be made up of a plurality of insulating films, stacked together, and may be of the same material as that of the interlayer insulating film 65. A wire trench, in which the second wire 68 is to be embedded, is formed in the interlayer insulating film 67. The second wire 68 is embedded via the barrier metal 70 in the wire trench.

The second wire 68 is such wire that is embedded via the barrier metal 70 in wire trenches formed in the interlayer insulating film 67 and in the etching stopper film 66. The second wire 68 is as one with the plug 69, which plug 69 is embedded via the barrier metal 70 in a pilot hole formed in the interlayer insulating film 65, in the protective insulating film 64 and in the hard mask film 63. The plug 69 is electrically connected to the second upper electrode 61 via the barrier metal 70. The second wire 68 and the plug 69 may be formed e.g., of Cu.

The barrier metal 70 is an electrically conductive film exhibiting a barrier characteristic. That is, the barrier metal coats the lateral and bottom sides of the second wire 68 and the plug 69 to prevent metal of the second wire 68 inclusive of the plug 69 from becoming diffused to the interlayer insulating films 65, 67 or to underlying layers. If the second wire 68 and the plug 69 are formed of metal elements, mainly Cu, the barrier metal 70 may be films of high melting metals or corresponding nitrides, such as tantalum, tantalum nitride, titanium nitride or wolfram carbonitride, or corresponding layered films. Preferably, the barrier metal 70 is formed of the same material as the second upper electrode 61. For example, if the barrier metal 70 has a layered structure of TaN (lower layer) and Ta (upper layer), it is preferred to use TaN, which is the lower layer material, as the second upper electrode 61. Or, if the barrier metal 50 has a layered structure of Ti (lower layer) and Ru (upper layer), it is preferred to use Ti, which is the lower layer material, as the second upper electrode 61.

The barrier insulating film 71 is such insulating film that is formed on the interlayer insulating film 67 provided with the second wire 68. The barrier insulating film has the role to prevent metal, such as copper, in the second wire 68, from becoming oxidized or from becoming diffused to upper layers. For the barrier insulating film 71, a SiC film, a SiCN film, a SiN film or a corresponding layered film(s) may be used.

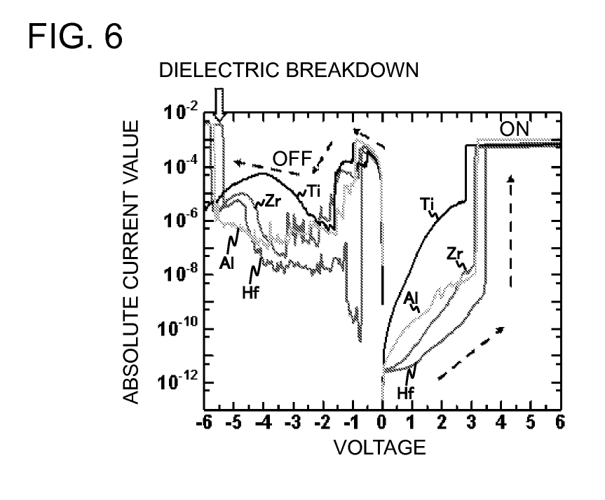

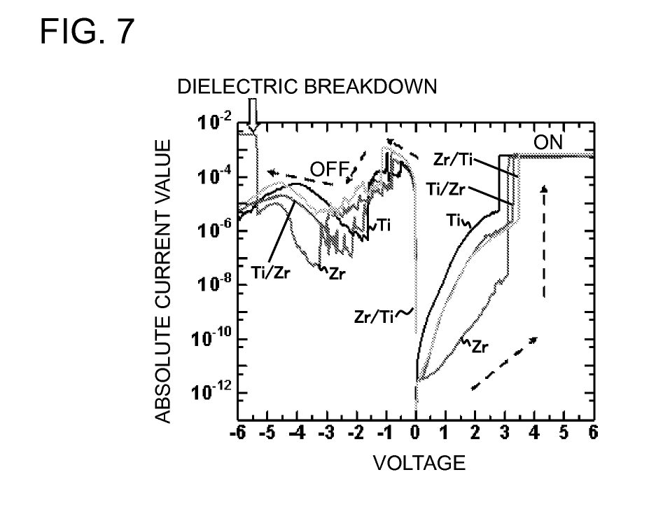

The operation of a two-terminal switch of Example 2 will now be described with reference to FIG. 6 and FIG. 7.

FIG. 6 shows current voltage characteristics for on/off operations of a two-terminal switch formed in the multi-layered wiring. Comparison is made of switches having an oxidation inhibiting film Ti of 1 nm, an oxidation inhibiting film Zr of 1 nm, an oxidation inhibiting film Hf of 1 nm and an oxidation inhibiting film Al of 1 nm. Initially, a positive voltage was applied to the first lower electrode 55a and swept, and the first upper electrode 60 as well as the second upper electrode 61 was grounded, such as to set the switch to an on-state. It may be found that the leakage current observed for the voltage of 1V to 3V is lower by not less than three orders of magnitude for the switches with the oxidation inhibiting films of Zr, Hf and Al than for the switch with the oxidation inhibiting film of Ti. That is, with the use of the Zr, Hf and Al as the oxidation inhibiting film material, the leakage current may be appreciably decreased. Then, a negative voltage was applied to the first lower electrode 55a and swept, and the first upper electrode 60 as well as the second upper electrode 61 was grounded, such as to set the switch to an off-state. It may be found that the leakage current observed in the vicinity of −3V is lower for the switches with the oxidation inhibiting films of Zr, Hf and Al than for the switch with the oxidation inhibiting film of Ti. That is, the switches with the oxidation inhibiting films of Zr, Hf and Al are in an off state with a higher resistance value. It may also be found that the dielectric breakdown voltage for the ion conductor layer, produced on additionally applying a negative voltage following the setting to the off-state, is higher for the switch having a Ti film as the oxidation inhibiting film.

FIG. 7 shows current voltage characteristics for the on/off operations of the two-terminal switch provided in an inner side of a multi-layered wiring. Comparison was made for switches having an oxidation inhibiting film of Ti of 1 nm, an oxidation inhibiting film of Zr of 1 nm, an oxidation inhibiting film of Ti of 0.5 nm/Zr of 0.5 nm (with the first lower electrode 55a side being Ti), and an oxidation inhibiting film of Zr of 0.5 nm/Ti of 0.5 nm (with the first lower electrode 55a side being Zr). Initially, a positive voltage was applied to the first lower electrode 55a and swept, and the first upper electrode 60 as well as the second upper electrode 61 was grounded, such as to set the switch to an on-state. It may be found that the leakage current observed for the voltage of 1V to 3V for the switches with the oxidation inhibiting films of Ti/Zr and Zr/Ti was halfway between that for the switch with the oxidation inhibiting films of Ti and that and for the switch with the oxidation inhibiting films of Zr. Then, a negative voltage was applied to the first lower electrode 55a and swept, and the first upper electrode 60 as well as the second upper electrode 61 was grounded, such as to set the switch to an off-state. It may be found that the current in the vicinity of −3V for the switches with the oxidation inhibiting films of Ti/Zr and Zr/Ti was also halfway between that for the switch with the oxidation inhibiting film of Ti and that for the switch with the oxidation inhibiting film of Zr. On the other hand, the dielectric breakdown voltage for the switches with the oxidation inhibiting films of Ti/Zr and Zr/Ti after the setting to the off-state was about equal to that for the switch with the oxidation inhibiting film of Ti, while being higher than that for the switch with the oxidation inhibiting film of Zr. From this it is seen that the leakage current for the switches with the oxidation inhibiting films of Ti/Zr and Zr/Ti may be made lower than that for the switch with the oxidation inhibiting film of Ti. It is also seen that the dielectric breakdown voltage following the setting to the off-state for the switches with the oxidation inhibiting films of Ti/Zr and Zr/Ti may be made higher than that for the switch with the oxidation inhibiting film of Zr. Since Ti is high in adhesion tightness, the adhesion performance of the oxidation inhibiting film with respect to the ion conductor layer 59b and the first lower electrode 55a may be increased to elevate the dielectric breakdown voltage. Also, Zr is effective to inhibit oxidation of metal of the first lower electrode 55a.

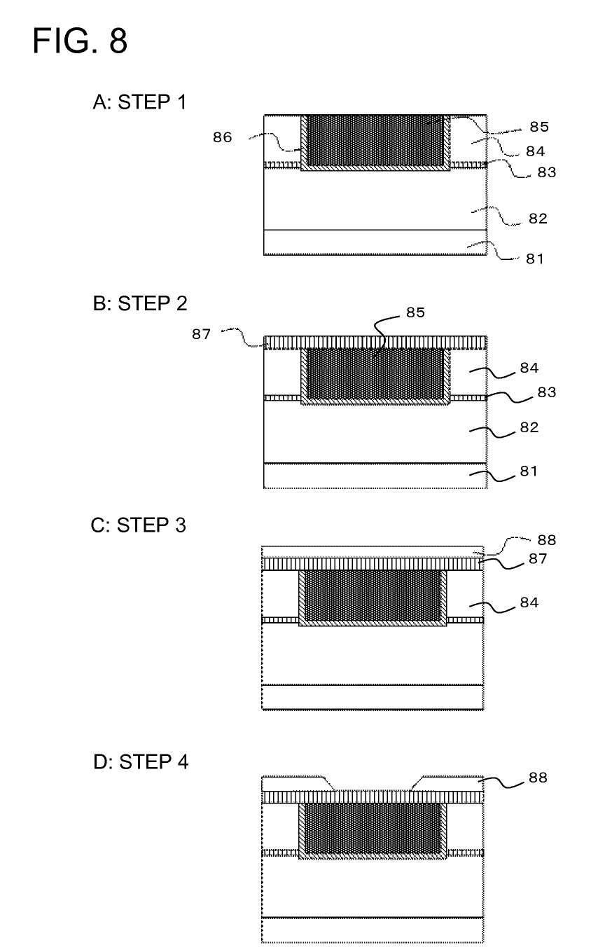

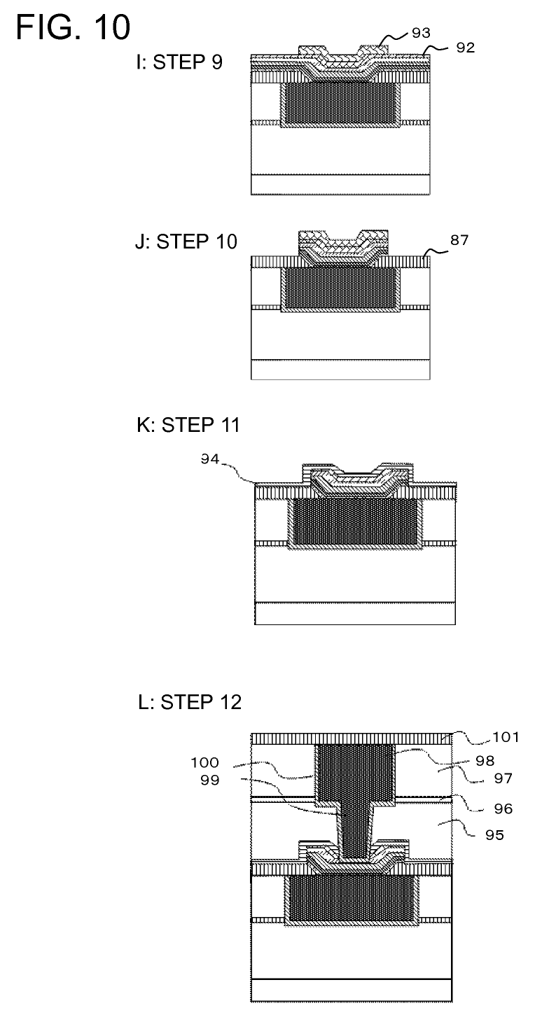

The manufacturing method for the semiconductor device according to Example 2 will now be described with reference to the drawings. FIG. 8 through to FIG. 10 depict cross-sectional views schematically showing exemplary process steps for the semiconductor device according to Example 2.

### [Step 1]

Referring to FIG. 8A (step 1), an interlayer insulating film 82, such as a silicon oxide film of 300 nm film thickness, was deposited on a semiconductor substrate 81, which is a substrate carrying a semiconductor device thereon. A barrier insulating film 83, such as a silicon nitride film of 50 nm film thickness, was deposited on the interlayer insulating film 82. Subsequently, an interlayer insulating film 84, such as a silicon nitride film of 300 nm film thickness, was deposited on the barrier insulating film 83. Then, using a lithography method inclusive of forming a photoresist, dry etching and photoresist removal, a wire trench was formed in each of the interlayer insulating film 84 and the barrier insulating film 83. A first wire 85 of e.g., copper was then embedded in the wire trench with interposition of a barrier metal 86, such as tantalum nitride/tantalum film with a film thickness of 5 nm/5 nm. The interlayer insulating films 82, 84 may be formed by plasma CVD. In forming the first wire 85, the barrier metal 86, such as a layered film of tantalum nitride/tantalum, is formed by e.g., a PVD method. A Cu seed is then formed by the PVD method, and copper is then embedded in the wire trench by an electroplating method. The resulting product is then heat-treated at a temperature not lower than 200° C., after which any excess copper other than that left in the trench is removed to complete the first wire. As a method for sequentially forming a copper wire, techniques commonly used in the pertinent technical field may be used. In a CMP (Chemical Mechanical Polishing) method, a wafer is brought into contact with a rotating polishing pad, as a polishing solution is allowed to flow on the wafer surface, such as to free the wafer of micro-sized surface irregularities produced during the multi-layered wiring forming process, thereby polishing and planarizing the wafer. By removing excess copper other than that embedded in the trench by polishing, an embedded wire (damascene wire) is formed, while the interlayer insulating film is planarized on polishing.

### [Step 2]

Referring to FIG. 8(B) (step 2), a barrier insulating film 87, such as a silicon nitride film of a film thickness of 50 nm, is formed on the interlayer insulating film 84 provided with the first wire 85. The barrier insulating film 87 may be formed by the plasma CVD method. The film thickness of the barrier insulating film 87 is preferably on the order of 10 to 50 nm.

### [Step 3]

Referring to FIG. 8C (step 3), a hard mask film 88, such as a silicon oxide film, is formed on the barrier insulating film 87 (step S3). From the perspective of maintaining a high etch select ratio during dry etching, the hard mask film 88 is preferably of a material different from the barrier insulating film 87. The hard mask film may be an insulating film or an electrically conductive film, whichever is desired. The hard mask film 88 may, for example, be a film of silicon oxide, silicon nitride, titanium nitride, titanium, tantalum or tantalum nitride. It may also be a silicon nitride/silicon oxide layered film.

### [Step 4]

Referring to FIG. 8D (step 4), an opening part is patterned in the hard mask film 88, using a photoresist, not shown. An opening part pattern is formed on the hard mask film 88 by dry etching using the photoresist as a mask. The photoresist is then removed by e.g., oxygen plasma ashing. It is not strictly necessary that dry etching is stopped at the upper surface of the barrier insulating film 87 but may get to an inner side of the barrier insulating film 87.

### [Step 5]

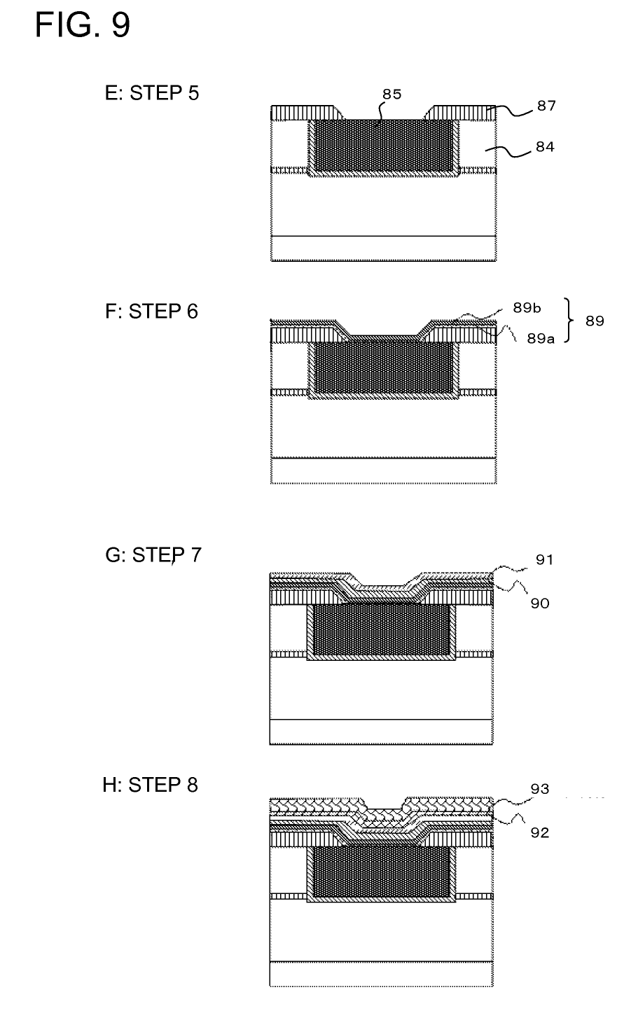

Referring to FIG. 9E (step 5), the part of the barrier insulating film 87, exposed from the opening part in the hard mask film 88, is etched back (dry etched) using the hard mask film 88 as a mask. This forms an opening part in the barrier insulating film 87 to expose the first wire 85 from the opening part formed in the barrier insulating film 87. An organic stripping processing is then carried out, using an amine based stripping solution, thereby removing a copper oxide formed on the exposed surface of the first wire 85 as well as etching off by-products formed during etchback. In etching back the barrier insulating film 87, reactive dry etching may be used to produce a tapered wall surface of the opening part of the barrier insulating film 87. For the reactive dry etching, a fluorocarbon containing gas may be used as an etching gas. It is preferred that the hard mask film 88 is completely removed during etchback. However, if the hard mask film is of an insulation material, it may also be left. The opening part in the barrier insulating film 87 is to be circular in shape, with the circle diameter being 300 to 500 nm. An oxide formed on the surface of the first wire 85 is removed by RF (Radio Frequency) etching that uses a non-reactive gas, which may be helium or argon.

### [Step 6]

Referring to FIG. 9F (step 6), Zr, Hf or Al is deposited on the barrier insulating film 87, provided with the first wire 85, to a film thickness not greater than 2 nm, for example, to a film thickness of 1 nm. The Zr, Hf or Al film, which is to be an oxidation inhibiting film 89a during the next step, may be formed by PVD or CVD. Additionally, a SiOCH based polymer film, containing silicon, oxygen, carbon and hydrogen, is formed as an ion conductor layer 89b by plasma CVD. A feedstock material of cyclic organic siloxane and helium as a carrier gas are allowed to flow into a reaction chamber. When the supply of the two materials is stabilized, with the pressure within the reaction chamber being constant, supply of the RF power is commenced. The feedstock material is supplied at a rate of 10 to 200 sccm, and helium is supplied via a feedstock vaporizer at a rate of 500 sccm, while helium is also directly supplied into the reaction chamber via a separate line at a rate of 500 sccm. When exposed to the feedstock material of the oxygen-containing SiOCH based polymer material in the course of deposition of the ion conductor layer 89b, the deposited layer of Zr, Hf or Al is spontaneously oxidized, and hence becomes an oxide. The layer of Zr, Hf or Al thus is turned into the oxidation inhibiting film 89a to form a part of the resistance variable layer 89. Since the moisture or the like remains attached to the opening part of the barrier insulating film 87, on account of the organic stripping processing, it is preferred that heat treatment is carried out for degassing under reduced pressure at a temperature of 250 to 350° C. before deposition of the resistance variable layer 89.

### [Step 7]

Referring to FIG. 9G (step 7), a first upper electrode 90, such as a ruthenium layer of 10 nm film thickness, and a second upper electrode 91, such as a tantalum layer 50 nm film thickness, are formed in this order on the resistance variable layer 89.

### [Step 8]

Referring to FIG. 9H (step 8), a hard mask film 92, such as a SiN film 30 nm film thickness, and another hard mask film 93, such as a SiO₂ film 90 nm film thickness, are deposited in this order on the second upper electrode 91. The hard mask films 92, 93 may be formed using the plasma CVD method. The hard mask films 92, 93 may be formed using the plasma CVD method which is the routine method used in the pertinent technical field. These hard mask films 92, 93 are preferably different sorts of films, and may respectively be a SiN film and a SiO₂ film, for example. The hard mask film 92 is preferably of the same material as that of a protective insulating film 94 as later mentioned and the barrier insulating film 87. That is, the material lying around the resistance variable layer is the same material throughout. In this case, the material interface is unified to prevent intrusion of moisture from outside as well as to prevent oxygen from being desorbed from the resistance variable layer itself. Although the hard mask film 92 may be formed by the plasma CVD method, it is preferred to use, for example, a SiN film obtained by processing a mixed gas of SiH₄/N₂ by high-density plasma to higher density.

### [Step 9]

Referring to FIG. 10I (step 9), a photoresist, not shown, for patterning a two-terminal switch part, is formed on the hard mask film 93. The hard mask film 93 is then dry-etched, using the photoresist as a mask, until the hard mask film 92 is exposed. The photoresist is then removed using oxygen plasma ashing and organic stripping.

### [Step 10]

Referring to FIG. 10J (step 10), the hard mask film 92, second upper electrode 91, first upper electrode 90 and the resistance variable layer 89 are etched in this order in succession, using the hard mask film 93 as a mask. Although it is preferred that the hard mask film 93 is completely removed during etchback, it may also be left. For example, if the second upper electrode 91 is Ta, Cl₂ based RIE may be applied, whereas, if the first upper electrode 90 is Ru, RIE may be applied using a Cl₂/O₂ mixed gas. Also, in etching the resistance variable layer 89, dry etching is to be stopped just at the barrier insulating film 87 which is the underlying surface. If the resistance variable layer 89 is a Ta-containing oxide, and the barrier insulating film 87 is a SiN film or a SiCN film, RIE may be performed provided that etching conditions are adjusted using CF₄ based, CF₄/Cl₂ based or CF₄/Cl₂/Ar based mixed gas. With the use of such hard mask RIE method, the resistance variable element part may be processed without subjecting it to oxygen plasma ashing destined for resist removal. In case oxidizing processing by oxygen plasma is to be performed following the machining, oxidizing plasma processing may be performed without dependency upon the resist stripping time.

### [Step 11]

Referring to FIG. 10K (step 11), a protective insulating film 94, for example, a silicon nitride film of 30 nm in film thickness, is deposited on the barrier insulating film 87 provided with the hard mask film 92, second upper electrode 91, first upper electrode 90 and with the resistance variable layer 89. The protective insulating film 94 can be formed by the plasma CVD method. However, in this case, a reduced pressure must be maintained within the reaction chamber before film deposition thus leading to a problem that oxygen is desorbed from the lateral side of the resistance variable layer 89 to increase the leakage current of the ion conductor layer. To suppress such problem from occurring, it is preferred that the film forming temperature for the protective insulating film 94 is set so as to be 250° C. or less. It is also preferred not to use a reducing gas in consideration that the reaction chamber is exposed under reduced pressure to a film-forming gas before film forming. For example, it is preferred that the protective insulating film is e.g., a SiN film produced from a SiH₄/N₂ mixed gas using high density plasma at a substrate temperature of 200° C.

Referring to FIG. 10L (step 12), an interlayer insulating film 95, such as a silicon oxide film, an etching stopper film 96, such as a silicon nitride film, and an interlayer insulating film 97, such as a silicon oxide film, are deposited in this order on the protective insulating film 94. A wire trench for a second wire 98 and a pilot hole for a plug 99 are then formed. Then, using a dual copper damascene wiring forming process, the second wire 98 of, for example, copper, and the plug 99 of, for example, copper, are formed at the same time in the wire trench and in the pilot hole, respectively, with interposition of a barrier metal 100 of, for example, tantalum nitride/tantalum. A barrier insulating film 101, such as a silicon nitride film, is then deposited on the interlayer insulating film 97 provided with the second wire 98. In forming the second wire 98, such process similar to that used in forming underlying layer wiring may be used. By using the same metal for the barrier metal 100 and the second upper electrode 91, it is possible to reduce the contact resistance between the plug 99 and the second upper electrode 91 to improve the switch performance. The interlayer insulating films 95, 97 may be formed by the plasma CVD method. To annul a step difference produced due to the two-terminal switch 82, it is possible to deposit the interlayer insulating film 95 to a thicker thickness and to polish and planarize the interlayer insulating film 95 by CMP to form the interlayer insulating film 95 to a desired film thickness.

### Example 3

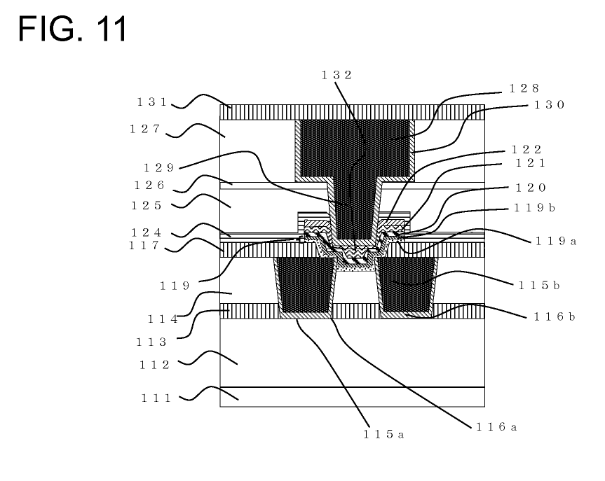

Referring to FIG. 11, a semiconductor device in which a three-terminal switch, upper electrodes of which are interconnected via an electrical field, is provided in an inner side of a multi-layered wiring, will now be explained by way of Example 3 of the semiconductor device. FIG. 11 depicts a cross-sectional view showing an exemplary configuration of the semiconductor device that makes use of the three-terminal switching element according to Example 3.

Example 3 of the semiconductor device includes a variable switching element in an inner side of a multi-layered wiring. A resistance variable layer 119 is interposed between a first upper electrode 120 and a first wire 115. The multi-layered wiring includes two different first wires (115a, 115b) and a plug 129 electrically connected to the first upper electrode 120 and to a second upper electrode 121. The first wire 115 is used at the same time as a lower electrode. The resistance variable layer 119 is connected via a sole opening part to the first wire 115 comprised of two copper parts. The opening part extends into an inner side of an interlayer insulating film 114 of the first wire 115. The method for forming the multi-layered wiring of FIG. 11 is the same as that for forming the multi-layered wiring of Example 2 (FIG. 5).

The multi-layered wiring includes, on top of a semiconductor substrate 111, an interlayer insulating film 112, a barrier insulating film 113, an interlayer insulating film 114, a barrier insulating film 117, a protective insulating film 124, an interlayer insulating film 125, an etching stopper film 126, an interlayer insulating film 127 and a barrier insulating film 131, layered in this order.

In the multi-layered wiring, first wires 115 (115a, 115b) are embedded in wire trenches formed in the interlayer insulating film 114 and in the barrier insulating film 113 via barrier metals 116 (116a, 116b). In the multi-layered wiring, a second wire 128 is embedded in wire trenches formed in the interlayer insulating film 127 and in the etching stopper film 126. The plug 129 is embedded in a pilot hole formed in the interlayer insulating film 125, the protective insulating film 124 and in a hard mask film 122, and is formed as one with the second wire 128. Lateral and bottom sides of the second wire 128 and the plug 129 are covered with a barrier metal 130.

Within an inner side of the multi-layered wiring, a three-terminal switch 132, made up of the resistance variable layer 119, first upper electrode 120 and the second upper electrode 121, stacked in this order, is formed within an opening part provided in the barrier insulating film 117. The three-terminal switch is arranged on a first wire A 115a, a first wire B 115b, the wall surface of the opening part in the barrier insulating film 117 and on the barrier insulating film 117. The hard mask film 122 is formed on top of the second upper electrode 121. A layered structure composed by the resistance variable layer 119, first upper electrode 120, second upper electrode 121 and the hard mask film 122 has its upper and lateral sides covered by the protective insulating film 124.

With the first wire A 115a and the first wire B 115b operating as a lower electrode of a three-terminal switch 132, that is, with the first wire A 115a and the first wire B 115b being used at the same time as the lower electrode of the three-terminal switch 132, it is possible to simplify the process and to lower the electrode resistance. By formulating at least two PRs of the mask set, by way of a supplementary step to the routine Cu damascene wiring forming process, the resistance variable element may be loaded in position, thus simultaneously lowering the resistance of the element and the cost.

The three-terminal switch (resistance variable element) 132 is a resistance variable non-volatile element, and may, for example, be a switching element that exploits migration of metal ions and an electro-chemical reaction in an ion conductor. The resistance variable element 132 is comprised of the resistance variable layer 119 interposed between the first wire A 115a and the first wire B 115b, operating as lower electrodes, and the upper electrodes 120, 121 electrically connected to the plug 129. In the three-terminal switch 132, the resistance variable layer 119 is directly contacted with the first wire A 115a and the first wire B 115b in a region of the opening part provided in the barrier insulating film 117. The plug 129 and the second upper electrode 121 are electrically connected to each other on the second upper electrode 121 via the barrier metal 130. The resistance variable element 132 exercises on/off control when the voltage applied to the element or when the element is passed through by the current. For example, the resistance variable element exercises on/off control by taking advantage of electrodiffusion of metal of the first wire A 115a and the first wire B 115b into the resistance variable layer 119. The second upper electrode 121 and the barrier metal 130 are formed of the same material. In this manner, the barrier metal 130 of the plug 129 is unified with the second upper electrode 121 of the resistance variable element 132 to reduce contact resistance to improve adhesion tightness and hence reliability.

The semiconductor substrate 111 is a substrate carrying thereon a semiconductor device. The semiconductor substrate 111 may be exemplified by a silicon substrate, a single crystal substrate, an SOI (Silicon on Insulator) substrate, a TFT (Thin Film Transistor) substrate and a substrate for manufacturing a liquid crystal.

The interlayer insulating film 112 is an insulating film formed on the semiconductor device 111. The interlayer insulating film 112, exhibiting a barrier characteristic, may be a silicon oxide film or a low dielectric constant film, such as SiOCH film, having specific inductive capacity lower than that of the silicon oxide film. The interlayer insulating film 112 may be composed by a plurality of insulating films stacked together.

A barrier insulating film 113 is such insulating film exhibiting a barrier characteristic and is interposed between the insulating films 112, 114. The barrier insulating film 113 plays the role of an etch stop layer at the time of machining a wire trench for the first wire 115. For the barrier insulating film 113, a SiN film, a SiC film, a SiCN layer or the like may be used. The barrier insulating film 113 is formed with a wire trench in which the first wire 115 is to be embedded. In this wire trench, the first wire 115 is embedded via a barrier metal 116. The barrier insulating film 113 may be omitted depending on the wire trench etch conditions selected.

The interlayer insulating film 114 is such an insulating film formed on the barrier insulating film 113. The interlayer insulating film 114 may be a silicon oxide film or a low dielectric constant film which is lower in specific inductive capacity than the silicon oxide film, such as SiOCH film. The interlayer insulating film 114 may be made up of a plurality of insulating films stacked together. A wire trench, in which the first wire 115 is to be embedded, is formed in the interlayer insulating film 114. The first wire 115 is embedded via the barrier metal 116 in the wire trench.

The first wire 115 is a wire embedded via the barrier metal 116 in wire trenches formed in the interlayer insulating film 114 and in the barrier insulating film 113. The first wire 115 operates at the same time as the lower electrode of the three-terminal switch 132 and is directly contacted with the resistance variable layer 119. An electrode layer, for example, may be inserted between the first wire 115 and the resistance variable layer 119. When the electrode layer is so formed, the electrode layer and the resistance variable layer 119 are deposited and processed at the same time by a consecutive process. The lower part of the resistance variable layer 119 is not connected to the underlying layer via a contact plug. For the first wire 115, such metal that is able to be diffused and to conduct ions in the resistance variable layer 119, for example, copper, is used. The first wire 115 may be alloyed with Al.

The barrier metal 116 is an electrically conductive film exhibiting a barrier characteristic. It serves as a coating for lateral and bottom sides of the first wire 115 to prevent metal of the first wire 115 from becoming diffused to the interlayer insulating film 114 and to underlying layers. In case the first wire 115 is formed of an element metal, mainly Cu, the barrier metal 116 may be formed of a high melting metal(s) or corresponding nitrides, such as tantalum (Ta), tantalum nitride (TaN), titanium nitride (TiN) or wolfram carbonitride (WCN) or a layered film(s) thereof.

The barrier insulating film 117 is formed on top of the interlayer insulating film 114 provided with the first wire 115, and performs the role of preventing metal of the first wire 115 from becoming oxidized. It also performs the role of preventing metal of the first wire 115 from becoming diffused into the interlayer insulating film 125 as well as the role as an etching stop layer during machining the upper electrodes 120, 121 and the resistance variable layer 119. For the barrier insulating film 117, a SiC film, a SiCN film, a SiN film or corresponding layered films may be used. The barrier insulating film 117 is preferably of the same material as the protective insulating film 124 or the hard mask film 122.

The barrier insulating film 117 has an opening part therein on top of the first wire 115. Within the opening part in the barrier insulating film 117, the first wire 115 is contacted with the resistance variable layer 119. The opening part in the barrier insulating film 117 is formed within a region of the first wire 115. In this manner, the three-terminal switch 132 may be formed on the surface of the first wire 115 suffering from just a limited amount of micro-sized crests or recesses. The wall surface of the opening part in the barrier insulating film 117 presents a tapered surface which becomes wider the more the wall surface is spaced apart from the first wire 115. The angle of the tapered surface of the opening part in the barrier insulating film 117 relative to the upper surface of the first wire 115 is set at 85° or less. By so doing, concentration of an electrical field in a region of the outer perimeter of a connection portion between the first wire 115 and the resistance variable layer 119 (the outer perimeter of the opening part in the barrier insulating film 117) is reduced, thus improving the dielectric strength.

The resistance variable layer 119 has its resistance varied, and is formed by an ion conductor layer 119b and an oxidation inhibiting film 119a. The ion conductor layer 119b may be formed of a material whose resistance is varied owing to the action of metal of the first wire 115 (lower electrode), such as diffusion or ion conduction. In case the resistance in the three-terminal switch 132 is to be varied depending on precipitation of metal ions, such film capable of ion conduction, such as a SiOCH based polymer film, containing silicon, oxygen, carbon and hydrogen, is used.

The oxidation inhibiting film 119a performs the role to prevent metal of the first wire 115 from becoming diffused into the ion conductor layer 119b due to plasma or heating during deposition of the ion conductor layer 119b. It also performs the role to prevent the first wire 115 from becoming oxidized leading to a state likely to promote diffusion. In the course of forming the ion conductor layer 119b, metals in the oxidation inhibiting film 119a, that is, Zr, Hf or Al, are turned into zirconium oxide, hafnium oxide or aluminum oxide, which will form a part of the resistance variable layer 119. An optimum film thickness of metal in the oxidation inhibiting film 119a is most preferably 2 nm and may desirably be not less than 0.5 nm and not greater than 3 nm. If the film thickness is thinner than this range, the copper wire surface may become oxidized only slightly. If, on the other hand, the film thickness is thicker than the range, the metal material is not fully oxidized but may be left as metal. The resistance variable layer 119 is formed on the first wire 115, on the tapered surface of the opening part in the barrier insulating film 117 and on the barrier insulating film 117. An outer rim part of a connecting portion of the first wire 115 to the resistance variable layer 119 is provided at least along the tapered surface of the opening part of the barrier insulating film 117.

The oxidation inhibiting film 119a may be a layered film structure of Ti with Zr, Hf or Al, or a film formed by a mixture of Ti with Zr, Hf or Al. Since Ti is high in tight adhesion performance, it may enhance tightness of adhesion to the ion conductor layer 119b as well as to the first wire 115 to enhance a dielectric breakdown voltage.

The oxidation inhibiting film 119a may also be formed by oxidizing a layered structure of Hf—Zr, Hf—Al or Zr—Al or by oxidizing a film of mixed metal of Hf—Zr, Hf—Al or Zr—Al. It is desirable not to use, for the wire changeover switch, as such, a high specific inductive capacity material that will possibly cause signal delay. Thus, such metal that, when oxidized, is enhanced in specific inductive capacity as oxide, is layered or mixed together with such metal that, when oxidized, is lower in specific inductive capacity as oxide than the first-stated metal. This will lower the overall specific inductive capacity of the switch.

The first upper electrode 120 is a lower layer side electrode of the upper electrode of the three-terminal switch 132, and is directly contacted with the resistance variable layer 119. For the first upper electrode 120, such metal is used that is less liable to be ionized or that is less susceptible to diffusion or ion conduction in the resistance variable layer 119 than the metal of the first wire 115. Such a metal material that has an absolute value of the free energy of oxidation than the metal component (Ta) of the resistance variable layer 119 is preferred. For the first upper electrode 120, Pt or Ru, for example, may be used. In case the first upper electrode 120 is composed mainly of Pt, Ru or the like, oxygen may be added thereto or a layer added by oxygen may be layered together.

The second upper electrode 121 is an upper layer side electrode in the upper electrode of the three-terminal switch 132, and is formed on the first upper electrode 120. The second upper electrode 121 plays the role to protect the first upper electrode 120. That is, with the second upper electrode 121 protecting the first upper electrode 120, it is possible to suppress damages to the first upper electrode 120 during the machining process to maintain the switching characteristic of the three-terminal switch 132. For the second upper electrode 121, Ta, Ti, W, Al or nitrides thereof, for example, may be used. The second upper electrode 121 is preferably of the same material as the barrier metal 130. The second upper electrode 121 is electrically connected to the plug 129 via the barrier metal 130. The diameter (or the area) of the region of contact of the second upper electrode 121 with the plug 129, more precisely the barrier metal 130, is set so as to be smaller than the diameter (or the area) of a region of contact of the first wire 115 with the resistance variable layer 119. By so doing, it is possible to suppress non-optimum embedding of plating, for example, copper plating, in the pilot hole provided in the interlayer insulating film 125 that is to be a connection portion of the second upper electrode 121 to the plug 129, thereby suppressing voids from being produced.

The hard mask film 122 is such film that operates as a hard mask in etching the second upper electrode 121, first upper electrode 120 and the resistance variable layer 119. For the hard mask film 122, a SiN film, as an example, may be used. Preferably, the hard mask film 122 is formed of the same material as that of the protective insulating film 124 or the barrier insulating film 117. That is, the material lying around the three-terminal switch 132 is the same material throughout. In this case, the material interface is unified to prevent intrusion of moisture from outside as well as to prevent oxygen from being desorbed from the three-terminal switch 132 itself.

The protective insulating film 124 is an insulating film having a function to protect the three-terminal switch 132 from being damaged and to prevent oxygen from being desorbed from the resistance variable layer 119. For the protective insulating film 124, a SiN film or a SiCN film, for example, may be used. Preferably, the protective insulating film 124 is of the same material as that of the hard mask film 122 or the barrier insulating film 117. If so, the protective insulating film 124, barrier insulating film 117 and the hard mask film 122 may be unified to improve tight interfacial adhesion to enable optimum protection of the three-terminal switch 132.

The interlayer insulating film 125 is an insulating film formed on the protective insulating film 124. For the interlayer insulating film 125, a silicon oxide film, a SiOC film or a low dielectric constant film, such as SiOCH film, lower in specific inductive capacity than the silicon oxide film, may be used. The interlayer insulating film 125 may be a layered film structure formed by layering a plurality of insulating films, and may be of the same material as the interlayer insulating film 127. A pilot hole, in which the plug 129 is to be embedded, is formed in the interlayer insulating film 125. The plug 129 is embedded via the barrier metal 130 in the pilot hole.

The etching stopper film 126 is an insulating film interposed between the interlayer insulating films 125, 127. The etching stopper film 126 plays the role as an etching stop layer during machining a wire trench for the second wire 128. For the etching stopper film 126, a SiN film, a SiC film or a SiCN film, for example, may be used. A wire trench, in which the second wire 128 is to be embedded, is formed in the etching stopper film 126. The second wire 128 is embedded in the wire trench via the barrier metal 130. The etching stopper film 126 may be omitted depending on the wire trench etch conditions selected.

The interlayer insulating film 127 is an insulating film formed on the etching stopper film 126. As the interlayer insulating film 127, a silicon oxide film, a SiOC film or a low dielectric constant film, such as SiOCH film, which is lower in specific inductive capacity than the silicon oxide film, for example, may be used. The interlayer insulating film 127 may be made up of a plurality of insulating films stacked together, and may be of the same material as that of the interlayer insulating film 125. A wire trench, in which the second wire 128 is to be embedded, is formed in the interlayer insulating film 127. The second wire 128 is embedded via the barrier metal 130 in the wire trench.

The second wire 128 is such wire that is embedded via the barrier metal 130 in wire trenches formed in the interlayer insulating film 127 and in the etching stopper film 126. The second wire 128 is as-one with the plug 129, which plug 129 is embedded via the barrier metal 130 in a pilot hole formed in the interlayer insulating film 125, protective insulating film 124 and in the hard mask film 122. The plug 129 is electrically connected to the second upper electrode 121 via the barrier metal 130. The second wire 128 and the plug 129 may be formed of, for example, Cu. The diameter (or the area) of the region of contact of the plug 129, more precisely the barrier metal 130, with the second upper electrode 121, is set so as to be smaller than the diameter (or the area) of a region of contact of the first wire 115 with the resistance variable layer 119, such as to suppress non-optimum embedding of the plating in the pilot hole.

The barrier metal 130 is an electrically conductive film having a barrier characteristic to prevent metal of the second wire 128 inclusive of the plug 129 from being diffused to the interlayer insulating films 125, 127 and to underlying layers. This is accomplished by the barrier metal coating lateral and bottom sides of the second wire 128 and the plug 129. In case the second wire 128 and the plug 129 are formed of an element metal, mainly Cu, the barrier metal 130 may be formed of high melting metals, corresponding nitrides or layered film structures thereof. The high melting metals and their corresponding nitrides may be exemplified by tantalum (Ta), tantalum nitride (TaN), titanium nitride (TiN) and wolfram carbonitride (WCN). The barrier metal 130 is preferably of the same material as the second upper electrode 121. For example, if the barrier metal 130 is a layered structure of TaN (lower layer)/Ta (upper layer), it is desirable that TaN, as the lower layer material, is used as the second upper electrode 121. Or, if the barrier metal 130 is a layered structure of Ti (lower layer)/Ru (upper layer), it is desirable that Ti, as the lower layer material, is used as the second upper electrode 121.

The barrier insulating film 131 is an insulating film formed on top of the interlayer insulating film 127 provided with the second wire 128, and has the role to prevent metal of the second wire 128, such as Cu, from being oxidized or from becoming diffused to upper layers. For the barrier insulating film 131, a SiC film, a SiCN film, a SiN film or a layered film structures thereof may be used.

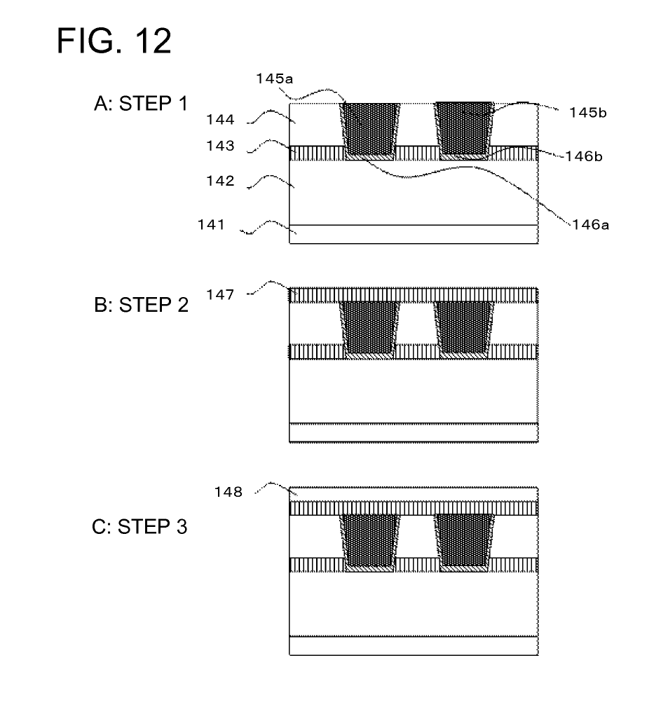

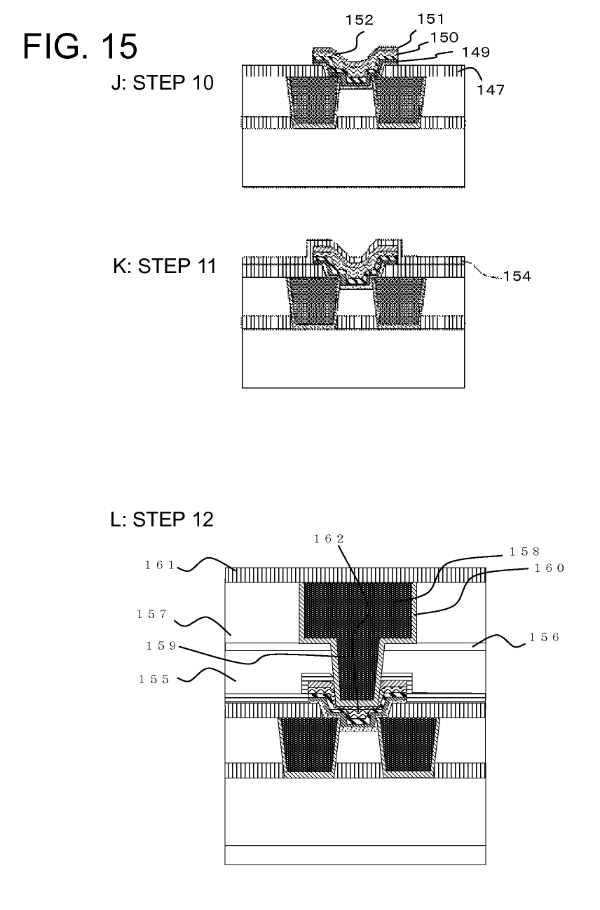

A method for manufacturing the semiconductor device according to Example 3 will now be described with reference to the drawings. FIG. 12 through to FIG. 15 depict cross-sectional views for illustrating the semiconductor device according to Example 3.

### [Step 1]

Referring first to FIG. 12A (step 1), an interlayer insulating film 142, such as a silicon oxide film of 300 nm in film thickness, is deposited on a semiconductor substrate 141, such as a substrate carrying thereon a semiconductor device. A barrier insulating film 143, such as a SiN film of 30 nm in film thickness, is then formed on the interlayer insulating film 142. An interlayer insulating film 144, such as a silicon oxide film of 200 nm in film thickness, is then deposited on the barrier insulating film 143. Then, two trenches for wires are formed in the interlayer insulating film 144 and in the barrier insulating film 143, using a photolithography method inclusive of photoresist formation, dry etching and photoresist removal. A first wire A 145a and a first wire B 145b, both being e.g., of copper, are then embedded in the trenches via a barrier metal A 146a and a barrier metal B 146b, each being e.g., a TaN/Ta film with film thicknesses of 5 nm/5 nm. In the step 1, the interlayer insulating films 142, 144 may be formed by plasma CVD (Chemical Vapor Deposition). By the plasma CVD (Chemical Vapor Deposition) is meant such a technique in which a gaseous feedstock or a gasified liquid feedstock is supplied in succession into a reaction chamber placed under a reduced pressure, and in which gas molecules are excited by the plasma energy to form an uninterrupted film on a substrate by a gaseous phase reaction or a substrate surface reaction. In forming the first wire A 145a and the first wire B 145b in the step 1, the barrier metal 146a, 146b, each being e.g., a TaN/Ta layered film, are formed by, for example, a PVD method. A Cu seed is then formed by the PVD method. Then, copper is embedded by electroplating and heat treatment is carried out at a temperature not lower than 200° C. Thereafter, excess copper other than that in the trenches is removed by the CMP method to form the first wires. In forming such copper wires, any of conventional techniques known in the pertinent technique may be used. The CMP (Chemical Mechanical Polishing) is such a method in which a wafer is brought into contact with a rotating polishing pad, as a polishing solution is caused to flow on the wafer surface, such as to free the wafer of irregular surface crests/recesses produced during the multi-layered copper wiring forming process, thereby polishing and planarizing the wafer. The excess copper embedded in the trenches is polished to form an embedded wire (damascene wire), or the interlayer insulating films are polished and planarized.

### [Step 2]

Referring now to FIG. 12B (step 2), a barrier insulating film 147, such as a SiCN of 30 nm in film thickness, is formed on the interlayer insulating film 144 provided with the first wire A 145a and with the first wire B 145b. The barrier insulating film 147 may be formed by the plasma CVD method. Preferably, the barrier insulating film 147 has a film thickness of the order of 10 to 50 nm.

### [Step 3]

Referring then to FIG. 12C (step 3), a hard mask film 148, for example, a silicon oxide film, is formed on the barrier insulating film 147. It is preferred that, from the perspective to set a larger etch select ratio in dry etching, the hard mask film 148 is of a material different from the material of the barrier insulating film 147. The hard mask film may be an insulating film or an electrically conductive film, whichever is desired. For the hard mask film 148, a silicon oxide film, a silicon nitride film, TiN, Ti, Ta or TaN, for example, may be used. A layered SiN/SiO₂ film structure may be used.

### [Step 4]

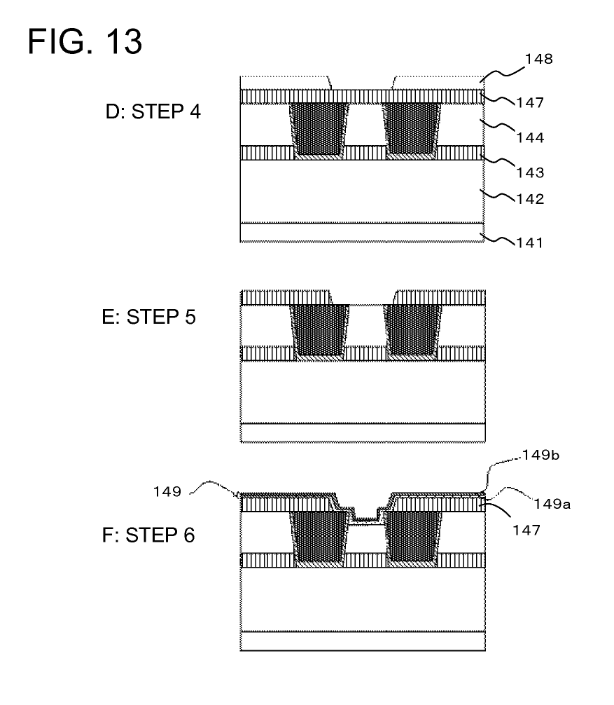

Referring to FIG. 13D (step 4), an opening part is patterned in the hard mask film 148, using a photoresist, not shown. An opening part pattern is formed in the hard mask film 148 by dry etching, using the photoresist as a mask. Subsequently, the photoresist is stripped, using oxygen plasma ashing, as an example. It is not strictly necessary that dry etching is stopped just on reaching the upper surface of the barrier insulating film 147, such that it may be extended well into an inner part of the barrier insulating film 147.

### [Step 5]

Then, using the hard mask film 148 as a mask, the part of the barrier insulating film 147, exposed from the opening part in the hard mask film 148, is etched back (dry etched), as shown in FIG. 13E (step 5). This forms an opening part in the barrier insulating film 147 such as to expose the first wire A 145a and the first wire B 145b from the opening part in the barrier insulating film 147. At this time, the opening part may be extended into the inner part of the interlayer insulating film. Then, organic stripping processing is performed using an amine-based stripping solution to remove copper oxide formed on the exposed surfaces of the first wire A 145a and the first wire B 145b as well as to remove etchback by-products. Preferably, the hard mask film 148 is completely removed in the step 5 in the course of the etchback. However, the hard mask film may also be left if it is of an insulating material. The opening part in the barrier insulating film 147 is in the shape of a circle, a square or a quadrangle, with the diameter of the circle or one side of the quadrangle being 20 nm to 500 nm. In the step 5, reactive dry etching may be used for etchback of the barrier insulating film 147 in order to produce a tapered wall surface of the opening part of the barrier insulating film 147. In reactive ion etching, a fluorocarbon containing gas may be used as an etching gas.

### [Step 6]

Then, as shown in FIG. 13F (step 6), a SiOCH based polymer film, containing silicon, oxygen, carbon and hydrogen, is formed to a film thickness of 6 nm by plasma CVD on the barrier insulating film 147 provided with the first wire A 145a and with the first wire B 145b. The polymer film is formed as an ion conductor layer 149b that composes a 149. A feedstock material of cyclic organic siloxane and helium as a carrier gas are allowed to flow into a reaction chamber. When the supply of the two materials is stabilized, with the pressure within the reaction chamber being constant, supply of the RF power is commenced. The feedstock material is supplied at a rate of 10 to 200 sccm, and helium is supplied into the reaction chamber via a feedstock vaporizer at a rate of 500 sccm, while also being supplied directly into the chamber via a separate line at a rate of 500 sccm. Since the moisture or the like remains attached to the opening part of the barrier insulating film 147, it is preferred that heat treatment for degassing is carried out under reduced pressure at a temperature of 250° to 350° C. before deposition of the resistance variable layer 149. At this time, care must be exercised to carry out the heat treatment in vacuum or under a nitrogen atmosphere so that the copper surface will not be re-oxidized. In the step 6, before deposition of the resistance variable layer 149, gas cleaning with H₂ gas or plasma cleaning may be performed on the parts of the first wire A 145a and the first wire B 145b exposed from the opening part of the barrier insulating film 147. By so doing, it is possible to suppress oxidation of Cu in the first wire A 145a and the first wire B 145b and to suppress thermal diffusion (migration) of copper in the course of forming the resistance variable layer 149. Also, in the step 6, before deposition of the ion conductor layer 149b, a thin oxidation inhibiting film 149a of Zr, Hf or Al layer of 2 nm or less in film thickness is deposited by PVD such as to suppress oxidation of Cu of the first wire A 145a and the first wire B 145b. The Zr, Hf or Al layer of the oxidation inhibiting film 149a is oxidized into corresponding oxides during the formation of the ion conductor layer 149b. The processing of the step 6 is preferably performed using the plasma CVD method since it is necessary to have the resistance variable layer 149 embedded with optimum step coverage in the opening part suffering from step differences.

### [Step 7]

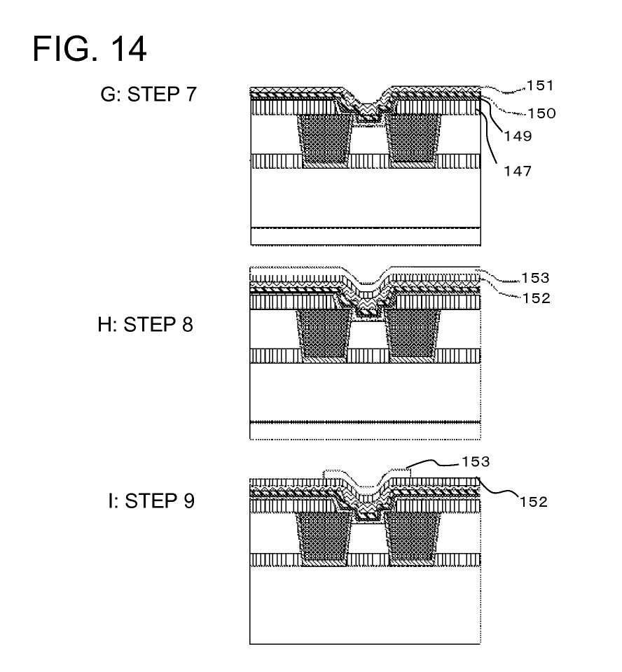

A first upper electrode 150 of e.g., Ru of 10 nm in film thickness and a second upper electrode 151 of e.g., Ta of 50 nm in film thickness are then formed in this order on the resistance variable layer 149, as shown in FIG. 14G (step 7). In order that the electrodes will be embedded in the opening part, equally suffering step differences, without forming voids, it is preferred to form Ru by e.g., an ALD method.

### [Step 8]

A hard mask film 152 of, for example, SiN film, 30 nm film thickness, and a hard mask film 153 of, for example, SiO₂, 200 nm film thickness, are then deposited in this order on the second upper electrode 151, as shown in FIG. 14H (step 8). In the step 8, the hard mask film 152 and the hard mask film 153 may be formed using plasma CVD. The hard mask films 152, 153 may be formed using the plasma CVD method which is the routine method used in the pertinent technical field. These hard mask films 152, 153 are preferably different sorts of films, and may respectively be a SiN film and a SiO₂ film, for example. It should be noticed that the hard mask film 152 is formed of the same material as that of a protective insulating film 154 and an insulation barrier film 147 which will be explained subsequently. That is, the material lying around the resistance variable element is the same material throughout. In this case, the material interface is unified to prevent intrusion of moisture from outside as well as to prevent oxygen from being desorbed from the resistance variable element itself. Although the hard mask film 152 may be formed by the plasma CVD method, since it is necessary to maintain a reduced pressure within the reaction chamber before film formation, such a problem is presented that oxygen is desorbed from the resistance variable layer 149 to increase the leakage current in the ion conduction layer due to oxygen defects. To suppress the problem, the film forming temperature is preferably 350° C. or less and more preferably 250° C. or less. It is also preferred not to use a reducing gas in consideration that the reaction chamber is exposed under reduced pressure to a film-forming gas before film forming. For example, it is preferred to use a SiN film produced from a SiH₄/N₂ mixed gas using high density plasma.

### [Step 9]

A photoresist, not shown, used for patterning a resistance variable element part, is formed on the hard mask film 153, as shown in FIG. 14I (step 9). Then, using the photoresist as a mask, the hard mask film 153 is dry-etched until the hard mask film 152 is exposed. The photoresist is then removed using oxygen plasma ashing and organic stripping.

### [Step 10]

Then, using the hard mask film 153 as a mask, the hard mask film 152, second upper electrode 151, first upper electrode 150 and the resistance variable layer 149 are dry etched in succession, as shown in FIG. 15J (step 10). Although it is desirable that the hard mask film 153 is completely removed during etchback, it may also be left. In the step 11, if the second upper electrode 151 is Ta, etching may be by RIE with the use of a Cl₂ based gas, whereas, if the first upper electrode 150 is Ru, etching may be by RIE with the use of a Cl₂/O₂ mixed gas. In etching the resistance variable layer 149, dry etching must be stopped as soon as the etching has reached the surface of the underlying barrier insulating film 147. In case the resistance variable layer 149 is a Ta-containing oxide and the barrier insulating film 147 is a SiN film or a SiCN film, etching may be by RIE, subject to adjusting the etch conditions using a mixed gas exemplified by CF₄ based, CF₄/Cl₂ based or CF₄/Cl₂/Ar based gas. With the use of the hard mask RIE method, the resistance variable layer 149 may be machined without exposing the variable resistance part to oxygen plasma ashing aimed at resist removal. If oxidization is performed after the machining, using oxygen plasma, oxidizing plasma processing may be performed without dependency on the resist stripping time.

### [Step 11]

The protective insulating film 154, such as SiN film of 30 nm in film thickness, is deposited on the barrier insulating film 147, provided with the hard mask film 152, the second upper electrode 151, the first upper electrode 150 and with the resistance variable layer 149, as shown in FIG. 15K (step 11). Although the protective insulating film 154 may be formed by the plasma CVD method, since it is necessary to maintain a reduced pressure within the reaction chamber before film forming, such a problem is presented that leakage current is increased in the ion conductor layer due to oxygen desorbed from the lateral side of the resistance variable layer 149. To suppress the problem, the film forming temperature is preferably 250° C. or less. It is also preferred not to use a reducing gas in consideration that the reaction chamber is exposed to a film-forming gas under reduced pressure before film forming. For example, it is preferred to form a SiN film prepared from a SiH₄/N₂ mixed gas using high density plasma at a substrate temperature of 200° C.

### [Step 12]

An interlayer insulating film 155, such as SiOC, an etching stopper film 156, such as a silicon nitride film, and an interlayer insulating film 157, such as a silicon nitride film, are deposited in this order on the protective insulating film 154, as shown in FIG. 15L (step 12). A wire trench for a second wire 158 and a pilot hole for a plug 159 are then formed. Using a dual copper damascene wiring forming process, the second wire 158 of e.g., Cu and the plug 159 of e.g., Cu are simultaneously formed in the wire trench and in the pilot hole via a barrier metal 160 of e.g., TAn/Ta. A barrier insulating film 161, such as a SiN film, is then deposited on the interlayer insulating film 157 provided with the second wire 158. In the step 12, the second wire 158 may be formed using a process similar to one used in forming the underlying layer wire. The barrier metal 160 and the second upper electrode 151 are formed of the same material, whereby it is possible to reduce the contact resistance between the plug 159 and the second upper electrode 151 to improve the performance of the element, that is, to reduce the resistance of a three-terminal switch 162 during the on-time. In the step 12, the interlayer insulating films 155, 157 may be formed by plasma CVD. In the step 12, to annul the step difference produced due to the three-terminal switch 162, the interlayer insulating film 155 may be deposited to a thicker thickness and the material of the interlayer insulating film 155 is scraped off by CMP such as to planarize the film 155 to a desired film thickness.

Each disclosure of the above-listed Patent Literatures and the like is incorporated herein by reference. Modifications and adjustments of the exemplary embodiments and an example are possible within the scope of the overall disclosure (including the claims) of the present invention and based on the technical concept of the present invention. Various combinations and selections of various disclosed elements (including each element in each claim, each element in each exemplary embodiment and the example, and each element in each drawing) are possible within the scope of the claims of the present invention. That is, the present invention naturally includes various variations and modifications that could be made by those skilled in the art according to the overall disclosure including the claims and the technical concept. Particularly, any numerical range disclosed herein should be interpreted that any intermediate values or subranges falling within the disclosed range are also concretely disclosed even without specific recital thereof.

### REFERENCE SIGNS LIST

11, 21, 31, 41 first electrodes
12, 22, 32, 42 second electrodes
13, 59b, 89b, 119b, 149b ion conductor layers
23, 33, 43 first ion conductor layers
24, 36, 45 second ion conductor layers
44 metal layer
35 metal ion
34 metal bridge
46 low resistance silicon substrate
56, 81, 111, 141 semiconductor substrates
52, 54, 65, 67, 82, 84, 95, 97, 112, 114, 125, 127, 142, 144, 155, 157 interlayer insulating films
53, 57, 71, 83, 87, 101, 113, 117, 131, 143, 147, 161 barrier insulating films
56, 70, 86, 100, 130, 160 barrier metals
116a, 146a barrier metals A
116, 146b barrier metals B
55, 85 first wires
55a first lower electrode
115a, 145a first wires A
115b, 145B first wires B
59, 89, 119, 149 resistance variable layers
68, 98, 128, 158 second wires
63, 88, 92, 93, 122, 148, 152, 153 hard mask films
66, 96, 126, 156 etching stopper films
59a, 89a, 119a, 149a oxidation inhibiting films
60, 90, 120, 150 first upper electrodes
61, 91, 121, 151 second upper electrodes
64, 94, 124, 154 protective insulating films
69, 99, 129, 159 plugs
72 two-terminal switch
132, 162 three-terminal switches

What is claimed is:

1. A resistance variable element, comprising a first electrode, a second electrode and an ion conductor layer interposed between the first and second electrodes;
metal ions supplied from the first electrode into the ion conductor layer accepting electrons from the second electrode and being turned into metal which is precipitated; the metal cross-linking and interconnecting the first and second electrodes to provide for variations in resistance of the element; wherein,
the ion conductor layer is a stacked layer structure made up by a first ion conductor layer formed by a compound containing oxygen and carbon and a second ion conductor layer formed of metal oxide;
the metal oxide that forms the second ion conductor layer containing at least one out of zirconium oxide and hafnium oxide.

2. The resistance variable element according to claim 1, wherein,
the second ion conductor layer further contains aluminum oxide.

3. The resistance variable element according to claim 1, wherein,
the second ion conductor layer is one selected from the group consisting of a layered product of titanium oxide and zirconium oxide, a mixed product of titanium oxide and zirconium oxide, a layered product of titanium oxide and hafnium oxide, a mixed product of titanium oxide and hafnium oxide, a layered product of hafnium oxide and zirconium oxide, a mixed product of hafnium oxide and zirconium oxide, a layered product of hafnium oxide and aluminum oxide, a mixed product of hafnium oxide and aluminum oxide, a layered product of zirconium oxide and aluminum oxide and a mixed product of zirconium oxide, and aluminum oxide.

4. The resistance variable element according to claim 1, wherein,
the second ion conductor layer has a film thickness of 0.5 nm or more to 3 nm or less.

5. A resistance variable element, comprising
optional two of the resistance variable elements according to claim 1 arrayed side-by-side; the first electrodes of the two resistance variable elements being formed as one electrode, or the second electrodes of the two resistance variable elements being formed as one electrode to provide a three terminal structure.

6. The resistance variable element according to claim 1, wherein,
the first ion conductor layer is formed by a polymer film having a specific inductive capacity of 2.1 or higher to 3.0 or lower and mainly composed at least of silicon, oxygen and carbon.

7. A semiconductor device, comprising a multi-layered copper wiring on a semiconductor substrate thereof and the resistance variable element as stated in claim 1, the resistance variable element being disposed in an inner side of the multi-layered copper wiring, wherein,
the multi-layered copper wiring includes at least a copper wire(s) and a copper plug;
the resistance variable element being made up of an upper electrode as a second electrode, a lower electrode(s) as a first electrode and an ion conductor layer interposed in-between the upper electrode and the lower electrode(s);
the copper wire(s) being simultaneously used as the lower electrode(s); a barrier insulating film being formed on top of the copper wire(s);
the barrier insulating film being formed of silicon nitride;
an opening part that reaches the copper wire(s) being formed in the barrier insulating film;
the ion conductor layer and the upper electrode of the resistance variable element being sequentially embedded only in the opening part;
the upper electrode being formed of ruthenium;
the upper electrode being connected via a barrier metal to the copper plug;
the ion conductor layer being made up of a first ion conductor layer contacted with the copper wire(s) and a second ion conductor layer contacted with the upper electrode;
the first ion conductor layer being formed by a polymer film, having a specific inductive capacity of 2.1 or higher to 3.0 or lower, and mainly composed at least of silicon, oxygen and carbon.

8. A semiconductor device, comprising a multi-layered copper wiring on a semiconductor substrate thereof and the resistance variable element as stated in claim 5, the resistance variable element being disposed in an inner side of the multi-layered copper wiring, wherein,
the multi-layered copper wiring includes at least a copper wire(s) and a copper plug;
the resistance variable element being made up of two of lower electrodes as the first electrode, an upper electrode as the second electrode, and an ion conductor layer interposed in-between the upper electrode and the lower electrodes;
the copper wires being simultaneously used as two of the lower electrodes; a barrier insulating film being formed on top of the copper wires;
the barrier insulating film being formed of silicon nitride;
the barrier insulating film including a single opening part that reaches the copper wires which are both of the two lower electrodes;
the ion conductor layer and the upper electrode being sequentially embedded only in the opening part;
the upper electrode being formed of ruthenium;
the upper electrode being connected via a barrier metal to the copper plug;
the ion conductor layer being made up of a first ion conductor layer contacted with the copper wire(s) and a second ion conductor layer contacted with the upper electrode;
the first ion conductor layer being formed by a polymer film, having a specific inductive capacity of 2.1 or higher to 3.0 or lower, and mainly composed at least of silicon, oxygen and carbon.

9. A method for manufacturing a resistance variable element including a first electrode, a second electrode and an ion conductor layer interposed between the first and second electrodes; the ion conductor layer being a stacked layer structure of a first ion conductor layer formed by a compound containing oxygen and carbon and a second ion conductor layer formed of metal oxide; the method comprising:
forming at least one first electrode on the surface of a silicon substrate;
forming a metal layer containing at least one metal out of zirconium and hafnium on the silicon substrate; and
forming the first ion conductor layer formed by a compound containing oxygen and carbon on the metal layer in an oxidizing atmosphere;
the metal layer being simultaneously oxidized in the step of forming the first ion conductor layer in the oxidizing atmosphere to form the second ion conductor layer.

10. A method for manufacturing a semiconductor device including a multi-layered copper wiring arranged on a semiconductor substrate and the resistance variable element as stated in claim 1; the resistance variable element being disposed in an inner side of the multi-layered copper wiring; the multi-layered copper wiring of the semiconductor device including at least one copper wire; the method comprising:
forming a barrier insulating film on at least one copper wire that is used simultaneously as a lower electrode;
forming, in the barrier insulating film, an opening part that reaches the at least one copper wire;
forming, on the at least one copper wire in at least the opening part, a metal layer containing at least one metal out of zirconium and hafnium; and
forming a first ion conductor layer, formed by a compound containing oxygen and carbon, on the metal layer in an oxidizing atmosphere;
the metal layer being oxidized simultaneously in the forming the first ion conductor layer in the oxidizing atmosphere to form a second ion conductor layer.
